(19) United States
(12) Patent Application Publication
(10) Pub. No.: US 2025/0117542 A1
(43) Pub. Date: Apr. 10, 2025

(54) INTERACTIVE SPACE FOR TRACKING INTERACTIONS WITH AN ARTIFICIAL INTELLIGENCE MODEL

(71) Applicant: AUTODESK, INC., San Francisco, CA (US)

(72) Inventors: George William FITZMAURICE, Toronto (CA); Jo Karel VERMEULEN, East York (CA); Justin Frank MATEJKA, Newmarket (CA)

(21) Appl. No.: 18/762,111

(22) Filed: Jul. 2, 2024

Related U.S. Application Data
(60) Provisional application No. 63/588,256, filed on Oct. 5, 2023.

(51) Int. Cl. G06F 30/20; G06F 3/01; G06F 3/0482

(52) U.S. Cl. CPC G06F 30/20; G06F 3/017; G06F 3/0482

(57) ABSTRACT

In various embodiments, a computer-implemented method for displaying a prompt space comprises displaying a design space comprising one or more design objects, receiving a selection of a current location within the design space, and displaying the prompt space at a placement location within the design space based on the current location.

### CROSS-REFERENCE TO RELATED APPLICATIONS

This application claims priority benefit of the U.S. Provisional Patent Application titled, “TECHNIQUES FOR TRACKING INTERACTIONS WITH AN ARTIFICIAL INTELLIGENCE MODEL WHEN GENERATING A COMPUTER-AIDED DESIGN,” filed on Oct. 5, 2023, and having Ser. No. 63/588,256. The subject matter of this related application is hereby incorporated herein by reference.

### BACKGROUND

### Field of the Various Embodiments

The various embodiments relate generally to computer-aided design and artificial intelligence and, more specifically, to interactive space for tracking interactions with an artificial intelligence model.

### Description of the Related Art

Design exploration for three-dimensional (3D) objects generally refers to a phase of a design process during which a designer experiments with using various 3D objects within an overall 3D design. During this design phase, the designer usually generates and modifies numerous 3D objects to determine which 3D objects or versions of 3D objects work best within the overall 3D design. As is well-understood, manually generating and modifying even a relatively simple 3D object is typically very labor-intensive and time-consuming. Because the time allocated for generating a 3D design is usually limited, a designer normally can experiment with only a limited number of 3D objects for a given 3D design. Consequently, the designer inevitably uses sub-optimized 3D objects within the final 3D design and/or fails to use certain 3D objects altogether within the final 3D design, thereby reducing the overall quality of the final 3D design. Accordingly, various conventional computer-aided design (CAD) applications have been developed that attempt to automate more fully how 3D objects are generated and evaluated during the design exploration process.

One approach to automating how CAD applications generate and modify 3D objects within a 3D design involves implementing an artificial intelligence (AI) model, such as a generative machine learning (ML) model, to provide design guidance to the user or automatically synthesize or modify 3D objects in response to prompts provided by the user. A prompt provided to the AI model can be in the form of a query or design problem statement that specifies one or more design characteristics to which a generated or modified 3D object should adhere. The prompt can include any number of quantitative goals, physical objects, physical and functional constraints, and/or mechanical and geometric quantities that guide how the AI model should generate or modify the 3D object. The AI model generates a response to the prompt, such as a natural language text response (displayed in a prompt space) and/or a generated or modified 3D object (displayed in the design space) that satisfies the query or design characteristics specified in the prompt.

Typically a CAD application generates a graphical user interface (GUI) that includes the design space and a separate prompt space for interacting with the AI model. The design space displays the overall 3D design having one or more 3D objects that can include one or more 3D objects that have been automatically generated or modified by the AI model. The prompt space receives the user inputs that are used for generating the prompts to the AI model. The prompt space also displays a prompt history of previous interactions with the AI model, including the user inputs for generating the prompts and the text responses and/or image responses from the AI model to the prompts. For example, the prompt space can comprise a panel/window within the GUI that includes a dialog between the user and the AI model.

One drawback of the above approach is that navigating the prompt history is difficult and tedious for the user. For example, a user typically interacts with the AI model over large number of iterations to generate multiple designs. Over the iterations, the user inputs various prompts to guide the AI model to generate a design that the user desires. However, a conventional prompt history usually displays a long list of such prompt interactions with no information about which particular 3D objects or locations within the design space are associated with which prompt interactions included in the prompt history. As a result, the user has difficulty navigating through the prompt history to find a particular prompt or dialog that is useful to the user. Another drawback of the above approach is that the prompt space is not optimized for images or other types of generated designs. In particular, the prompt space displays the prompt history as a textual dialog representing communication sessions between the user and the AI model. Conventional systems thus have difficulty displaying images as part of the dialog within the prompt space in a manner that is easily searchable or readable by the user. Consequently, the user cannot readily reference the prompt history to effectively retrieve a particular design that the AI model provided or use previous interactions to determine which prompts have historically been effective to generate designs as intended. As a result, the design process while using such conventional systems is slowed, and the overall design quality of designs made using objects generated by the AI model is reduced.

As the foregoing illustrates, what is needed in the art are more effective techniques for interacting with AI models when using CAD applications.

### SUMMARY

Various embodiments disclose a computer-implemented method for displaying a prompt space comprises displaying a design space comprising one or more design objects, receiving a selection of a current location within the design space, and displaying the prompt space at a placement location within the design space based on the current location.

At least one technical advantage of the disclosed techniques relative to the prior art is that the disclosed techniques generate visual records representing separate and distinct interactions with an AI model within a prompt space. In this regard, in response to a user request to view a given portion of the prompt history between a user and an AI model, a design exploration application displays multiple records of interactions within that portion of the prompt history as distinct cards within a navigable 3D space. Each of the cards can be moved, linked, and modified by the user, enabling users to filter and organize records of interactions that are relevant to generating an overall 3D design within the design space. Further, the prompts included in the prompt cards are selectable for generating new prompts for the AI model, and objects included in the prompt cards are selectable for inclusion in an overall design within a design space. Accordingly, with the disclosed techniques, the design exploration application can provide many separate and distinct interactions with an AI model within a 3D space in a manner that enables a user to easily navigate, interact with, and modify the prompt history. Such techniques allow the user to easily reference and retrieve information from previous interactions with the AI model, thereby reducing the time the user needs to interact with AI model to produce desired 3D objects. Further, such techniques enable the design exploration application to display generated 3D designs as part of a prompt history in a manner that is easily searchable and readable to the user. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a conceptual illustration of a system configured to implement one or more aspects of the various embodiments;

FIG. 2 is a more detailed illustration of the design exploration application of FIG. 1, according to various embodiments;

FIG. 3 is an exemplar illustration of the design space and the prompt space of FIG. 2, according to various embodiments;

FIG. 4 is an exemplar illustration of prompt cards organized within the prompt space of FIG. 2, according to various embodiments;

FIG. 5 is an exemplar illustration of multiple versions of a prompt arranged as prompt cards within the prompt space of FIG. 2, according to various embodiments;

FIG. 6 is an exemplar illustration of a user interaction with a prompt card within the prompt space of FIG. 2, according to various embodiments;

FIG. 7 is an exemplar illustration of a contextual suggestion window generated within the prompt space of FIG. 2, according to various embodiments;

FIG. 8 sets forth a flow diagram of method steps for generating 3D objects, according to various embodiments;

FIG. 9 sets forth a flow diagram of method steps for displaying prompt cards within a prompt space, according to various embodiments;

FIG. 10 sets forth a flow diagram for responding to interactions with a prompt card, according to various embodiments; and

FIG. 11 depicts one architecture of a system within which the various embodiments may be implemented.

### DETAILED DESCRIPTION

In the following description, numerous specific details are set forth to provide a more thorough understanding of the various embodiments. However, it will be apparent to one skilled in the art that the inventive concepts may be practiced without one or more of these specific details. For explanatory purposes, multiple instances of like objects are symbolized with reference numbers identifying the object and parenthetical numbers(s) identifying the instance where needed.

### System Overview

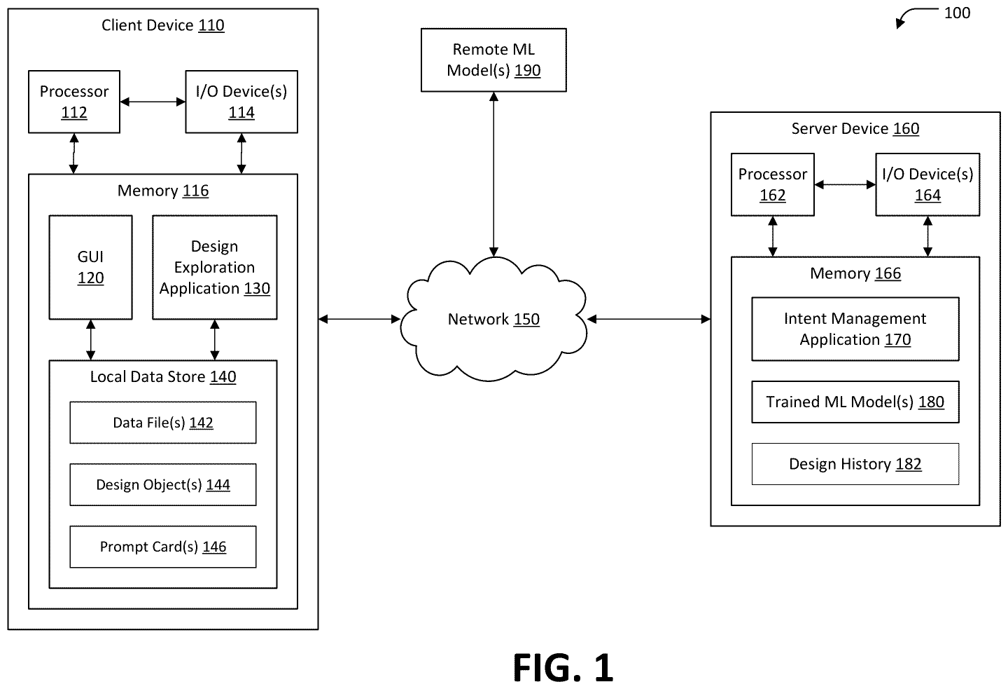

FIG. 1 is a conceptual illustration of a system 100 configured to implement one or more aspects of the various embodiments. As shown, in some embodiments, the system 100 includes, without limitation, a client device 110, a server device 160, and one or more remote machine learning (ML) models 190. The client device 110 includes, without limitation, a processor 112, one or more input/output (I/O) devices 114, and a memory 116. The memory 116 includes, without limitation, a graphical user interface (GUI) 120, a design exploration application 130, and a local data store 140. The local data store 140 includes, without limitation, one or more data files 142, one or more design objects 144, and one or more prompt cards 146. The server device 160 includes, without limitation, a processor 162, one or more I/O devices 164, and a memory 166. The memory 166 includes, without limitation, an intent management application 170, one or more trained ML models 180, and design history 182. In some other embodiments, the system 100 can include any number and/or types of other client devices, server devices, remote ML models, or any combination thereof.

Any number of the components of the system 100 can be distributed across multiple geographic locations or implemented in one or more cloud computing environments (e.g., encapsulated shared resources, software, data) in any combination. In some embodiments, the client device 110 and/or zero or more other client devices (not shown) can be implemented as one or more compute instances in a cloud computing environment, implemented as part of any other distributed computing environment, or implemented in a stand-alone fashion. In various embodiments, the client device 110 can be integrated with any number and/or types of other devices (e.g., one or more other compute instances and/or a display device) into a user device. Some examples of user devices include, without limitation, desktop computers, laptops, smartphones, and tablets.

In general, the client device 110 is configured to implement one or more software applications. For explanatory purposes only, each software application is described as residing in the memory 116 of the client device 110 and executing on the processor 112 of the client device 110. In some embodiments, any number of instances of any number of software applications can reside in the memory 116 and any number of other memories associated with any number of other compute instances and execute on the processor 112 of the client device 110 and any number of other processors associated with any number of other compute instances in any combination. In the same or other embodiments, the functionality of any number of software applications can be distributed across any number of other software applications that reside in the memory 116 and any number of other memories associated with any number of other compute instances and execute on the processor 112 and any number of other processors associated with any number of other compute instances in any combination. Further, subsets of the functionality of multiple software applications can be consolidated into a single software application.

In particular, the client device 110 is configured to implement a design exploration application 130 to generate designs for one or more 3D objects. In operation, the design exploration application 130 causes one or more ML models 180, 190 to synthesize designs for a 3D object based on any number of goals and constraints. The design exploration application 130 then presents the designs as one or more design objects 144 to a user in the context of a design space. In some embodiments, the user can explore and modify the one or more design objects via the GUI 120. Additionally or alternatively, the user can also include at least one of the design objects 144 for use in additional design and/or manufacturing activities.

In various embodiments, the processor 112 can be any instruction execution system, apparatus, or device capable of executing instructions. For example, the processor 112 could comprise a central processing unit (CPU), a digital signal processing unit (DSP), a microprocessor, an application-specific integrated circuit (ASIC), a neural processing unit (NPU), a graphics processing unit (GPU), a field-programmable gate array (FPGA), a controller, a microcontroller, a state machine, or any combination thereof. In some embodiments, the processor 112 is a programmable processor that executes program instructions to manipulate input data. In some embodiments, the processor 112 can include any number of processing cores, memories, and other modules for facilitating program execution.

The input/output (I/O) devices 114 include devices configured to receive input, including, for example, a keyboard, a mouse, and so forth. In some embodiments, the I/O devices 114 also includes devices configured to provide output, including, for example, a display device, a speaker, and so forth. Additionally or alternatively, the I/O devices 114 may further include devices configured to both receive and provide input and output, respectively, including, for example, a touchscreen, a universal serial bus (USB) port, and so forth.

The memory 116 includes a memory module, or collection of memory modules. In some embodiments, the memory 116 can include a variety of computer-readable media selected for their size, relative performance, or other capabilities: volatile and/or non-volatile media, removable and/or non-removable media, etc. The memory 116 can include cache, random access memory (RAM), storage, etc. The memory 116 can include one or more discrete memory modules, such as dynamic RAM (DRAM) dual inline memory modules (DIMMs). Of course, various memory chips, bandwidths, and form factors may alternately be selected. The memory 116 stores content, such as software applications and data, for use by the processor 112. In some embodiments, a storage (not shown) supplements or replaces the memory 116. The storage can include any number and type of external memories that are accessible to the processor 112 of the client device 110. For example, and without limitation, the storage can include a Secure Digital (SD) Card, an external Flash memory, a portable compact disc read-only memory, an optical storage device, a magnetic storage device, or any suitable combination of the foregoing.

Non-volatile memory included in the memory 116 generally stores one or more application programs including the design exploration application 130, and data (e.g., the data files 142 and/or the design objects stored in the local data store 140) for processing by the processor 112. In various embodiments, the memory 116 can include non-volatile memory, such as optical drives, magnetic drives, flash drives, or other storage. In some embodiments, separate data stores, such as one or more external data stores connected via the network 150 (“cloud storage”) can supplement the memory 116. In various embodiments, the design exploration application 130 within the memory 116 can be executed by the processor 112 to implement the overall functionality of the client device 110 to coordinate the operation of the system 100 as a whole.

In various embodiments, the memory 116 can include one or more modules for performing various functions or techniques described herein. In some embodiments, one or more of the modules and/or applications included in the memory 116 may be implemented locally on the client device 110, and/or may be implemented via a cloud-based architecture. For example, any of the modules and/or applications included in the memory 116 could be executed on a remote device (e.g., smartphone, a server system, a cloud computing platform, etc.) that communicates with the client device 110 via a network interface or an I/O devices interface.

The design exploration application 130 resides in the memory 116 and executes on the processor 112 of the client device 110. The design exploration application 130 interacts with a user via the GUI 120. In some embodiments, the design exploration application 130 and one or more separate applications (not shown) interact with the same user via the GUI 120. In various embodiments, the design exploration application 130 operates as a 3D design application to generate and modify an overall 3D design that includes one or more design objects 144. The design exploration application 130 interacts with a user via the GUI 120 in order to generate the one or more design objects 144 via direct user input (e.g., one or more tools to generate 3D objects, wireframe geometries, meshes, etc.) or via separate devices (e.g., the trained ML models 180, the remote ML models 190, separate 3D design applications, etc.). When generating the one or more design objects 144 via separate devices, the design exploration application 130 generates a prompt that effectively describes design-related intentions using one or more modalities (e.g., text, speech, images, etc.). The design exploration application 130 then causes the one or more of the ML models 180, 190 to operate on the generated prompt to generate a relevant design object 144. The design exploration application 130 receives the design object 144 from the one or more ML models 180, 190 and displays the design object 144 within the GUI 120. The user can select via the GUI 120 the design object 144 for use, such as incorporating the design object 144 in a larger 3D design.

In some embodiments, the design exploration application 130 operates as a 3D exploration application 130 to generate one or more prompt cards 146 representing records of interactions between the user via the client device 110 and the one or more ML models 180, 190. In such instances, the 3D exploration application via the GUI 120 generates an interactive space to display the one or more prompt cards 146. The 3D exploration application 130 provides various navigation tools (e.g., traversal controls, zoom controls, etc.) and/or interaction tools (e.g., brushes for inking portions of the interactive space and/or the one or more prompt cards 146) within the interactive space to enable the user to explore the existing prompt cards 146, modify the existing prompt cards 146 and/or extract portions of the prompt cards 146 for further actions (e.g., selecting design objects 144 for use in the design space and/or generating new prompts to input into the one or more ML models 180, 190).

The GUI 120 can be any type of user interface that allows users to interact with one or more software applications via any number and/or types of GUI elements. The GUI 120 can be displayed in any technically feasible fashion on any number and/or types of stand-alone display device, any number and/or types of display screens that are integrated into any number and/or types of user devices, or any combination thereof. The design exploration application 130 can perform any number and/or types of operations to directly and/or indirectly display and monitor any number and/or types of interactive GUI elements and/or any number and/or types of non-interactive GUI elements within the GUI 120. In some embodiments, each interactive GUI element enables one or more types of user interactions that automatically trigger corresponding user events. Some examples of types of interactive GUI elements include, without limitation, scroll bars, buttons, text entry boxes, drop-down lists, and sliders. In some embodiments, the design exploration application 130 organizes GUI elements into one or more container GUI elements (e.g., panels and/or panes).

The local data store 140 is a part of storage in the client device 110 that stores one or more design objects 144 included in an overall 3D design, one or more data files 142 associated with 3D design, and/or one or more prompt cards 146 representing visual records of interactions with the ML models 180, 190. For example, an overall 3D design for a building can include multiple stored design objects 144, including design objects 144 separately representing doors, windows, fixtures, walls, appliances, and so forth. The local data store 140 can also include data files 142 relating to a generated overall 3D design (e.g., component files, metadata, etc.). Additionally or alternatively, the local data store 140 includes data files 142 related to generating prompts for transmission to the one or more ML models 180, 190. For example, the local data store 140 can store one or more data files 142 for sketches, geometries (e.g., wireframes, meshes, etc.), images, videos, application states (e.g., camera angles used within a design space, tools selected by a user, etc.), audio recordings, and so forth.

The design objects 144 include geometries, textures, images, and/or other components that the design exploration application 130 uses to generate an overall 3D design. In various embodiments, the geometry of a given design object refers to any multi-dimensional model of a physical structure, including CAD models, meshes, and point clouds, as well as circuit layouts, piping diagrams, free-body diagrams, and so forth. In some embodiments, the design exploration application 130 stores multiple design objects 144 for a given 3D design and stores multiple iterations of a given target object that the ML models 180, 190. For example, the user can form an initial prompt using the design exploration application 130 and receive a first generated design object 144(1) from the trained ML model 180(1), then refine the prompt and receive a second generated design object 144(2) from the trained ML model 180(1).

The prompt cards 146 are one or more visualizations of records of one or more interactions between a given user and the ML models 180, 190. In some embodiments, a set of prompt cards 146 collectively represent a set of records comprising the prompt history of a given user or a group of users (e.g., a team of users in an organization). For example, the design exploration application 130 can store, as a prompt history, a record of a communication session between a user and the trained ML model 180. Upon storing the prompt history, the design exploration application 130 can generate one or more separate prompt cards 146 representing records of different portions of the communication session. In another example, the design exploration application 130 can generate a first subset of prompt cards 146 (e.g., 146(1)-146(7)) based on the prompt history of a first user interacting with the trained ML model 180 and can generate a second subset of prompt cards 146 (e.g., 146(8)-146(11)) based on the prompt history of a second user interacting with a remote ML model 190. In some embodiments, a prompt card 146 includes a record of a single interaction between the user and the ML model 180, 190, such as a single prompt that was transmitted to the ML model 180, 190 and a single response (e.g., a textual response, a generated image, and/or a generated design object 144) provided by the ML model 180, 190.

In various embodiments, the design exploration application 130 displays the one or more prompt cards 146 via the GUI 120 in the same space as the overall 3D design (e.g., in an area overlapping the design space). Alternatively, in some embodiments, the design exploration application 130 displays the one or more prompt cards 146 via the GUI 120 in a separate space than the space displaying as the overall 3D design. For example, the GUI 120 can display the one or more prompt cards 146 in an interactive prompt space that includes one or more virtual partitions (e.g., virtual walls and/or virtual dividers). The design exploration application 130 can arrange a set of prompt cards 146 on the vertical partitions and enable the user to ink the vertical partitions to indicate intent for one or more prompt cards 146 (e.g., groupings, selections, annotations, direct links, etc.). For example, the user can ink a line on the virtual partition connecting two prompt cards 146. The design exploration application 130 can then detect the inked line and respond by linking the two prompt cards 146.

The network 150 can be any technically feasible set of interconnected communication links, including a local area network (LAN), wide area network (WAN), the World Wide Web, or the Internet, among others. The network 150 enables communications between the client device 110 and other devices in network 150 via wired and/or wireless communications protocols, including Bluetooth, Bluetooth low energy (BLE), wireless local area network (WiFi), cellular protocols, satellite networks, and/or near-field communications (NFC).

The server device 160 is configured to communicate with the design exploration application 130 to generate one or more design objects 144. In operation, the server device 160 executes the intent management application 170 to process a prompt generated by the design exploration application 130, select one or more ML models 180, 190 trained to generate design objects 144 in response to the contents of the prompt, and input the prompt into the selected ML models 180, 190. Once the selected ML models 180, 190 generate the design objects 144 that are responsive to the prompt, the server device 160 transmits the generated design objects to the client device 110, where the generated design objects 144 are usable by the design exploration application 130.

In various embodiments, the processor 162 can be any instruction execution system, apparatus, or device capable of executing instructions. For example, the processor 162 could comprise a central processing unit (CPU), a digital signal processing unit (DSP), a microprocessor, an application-specific integrated circuit (ASIC), a neural processing unit (NPU), a graphics processing unit (GPU), a field-programmable gate array (FPGA), a controller, a microcontroller, a state machine, or any combination thereof. In some embodiments, the processor 162 is a programmable processor that executes program instructions to manipulate input data. In some embodiments, the processor 162 can include any number of processing cores, memories, and other modules for facilitating program execution.

The input/output (I/O) devices 164 include devices configured to receive input, including, for example, a keyboard, a mouse, and so forth. In some embodiments, the I/O devices 164 also includes devices configured to provide output, including, for example, a display device, a speaker, and so forth. Additionally or alternatively, the I/O devices 164 may further include devices configured to both receive and provide input and output, respectively, including, for example, a touchscreen, a universal serial bus (USB) port, and so forth.

The memory 166 includes a memory module, or collection of memory modules. In some embodiments, the memory 166 can include a variety of computer-readable media selected for their size, relative performance, or other capabilities: volatile and/or non-volatile media, removable and/or non-removable media, etc. The memory 166 can include cache, random access memory (RAM), storage, etc. The memory 166 can include one or more discrete memory modules, such as dynamic RAM (DRAM) dual inline memory modules (DIMMs). Of course, various memory chips, bandwidths, and form factors may alternately be selected. The memory 166 stores content, such as software applications and data, for use by the processor 162. In some embodiments, a storage (not shown) supplements or replaces the memory 166. The storage can include any number and type of external memories that are accessible to the processor 162 of the server device 160. For example, and without limitation, the storage can include a Secure Digital (SD) Card, an external Flash memory, a portable compact disc read-only memory, an optical storage device, a magnetic storage device, or any suitable combination of the foregoing.

Non-volatile memory included in the memory 166 generally stores one or more application programs including the intent management application 170 and one or more trained ML models 180, and data (e.g., design history 182) for processing by the processor 112. In various embodiments, the memory 166 can include non-volatile memory, such as optical drives, magnetic drives, flash drives, or other storage. In some embodiments, separate data stores, such as one or more external data stores connected via the network 150 can supplement the memory 166. In various embodiments, the intent management application 170 and/or the one or more ML models 180 within the memory 166 can be executed by the processor 162 to implement the overall functionality of the server device 160 to coordinate the operation of the system 100 as a whole.

In various embodiments, the memory 166 can include one or more modules for performing various functions or techniques described herein. In some embodiments, one or more of the modules and/or applications included in the memory 166 may be implemented locally on the client device 110, server device 160, and/or may be implemented via a cloud-based architecture. For example, any of the modules and/or applications included in the memory 166 could be executed on a remote device (e.g., smartphone, a server system, a cloud computing platform, etc.) that communicates with the server device 160 via a network interface or an I/O devices interface. Additionally or alternatively, the intent management application 170 could be executed on the client device 110 and can communicate with the trained ML models 180 operating at the server device 160.

In various embodiments, the intent management application 170 receives a prompt from the design exploration application 130 and inputs the prompt into an applicable ML model 180, 190. In some embodiments, one or more of the ML models 180, 190 are trained to respond to specific types of inputs, such as a ML model that is trained to generate design objects from a specific combination of modalities (e.g., text and images). In such instances, the intent management application 170 processes a prompt to determine the modalities of the data that are included in the prompt and identifies one or more ML models 180, 190 that have been trained to respond to such a combination of modalities. Upon identifying the one or more ML models, the intent management application 170 selects an ML model (e.g., the trained ML model 180(1)) and inputs the prompt into the selected ML model 180(1).

The trained ML models 180 include one or more generative ML models that have been trained on a relatively large amount of existing data and optionally any number of results (e.g., design objects 144 and evaluations provided by the user) to perform any number and/or types of prediction tasks based on patterns detected in the existing data. In various embodiments, the remote ML models 190 are trained ML models that communicate with the server device 160 to receive prompts via the intent management application 170. In some embodiments, the trained ML model 180 is trained using various combinations of data from multiple modalities, such as textual data (e.g., design intent text), image data, sound data, and so forth. The trained ML model 180 and/or the remote ML model 190 trained using at least two modalities of data are also referred to herein as a multimodal ML model. For example, in some embodiments, the one or more trained ML models 180 can include a third-generation Generative Pre-Trained Transformer (GPT-3) model, a specialized version of a GPT-3 model referred to as a “DALL-E2” model, a fourth-generation Generative Pre-Trained Transformer (GPT-4) model, and so forth. In various embodiments, the trained ML models 180 can be trained to generate design objects from various combinations of modalities. Such combinations include text, a CAD object, a geometry, an image, a sketch, a video, an application state, an audio recording, etc.).

The design history 182 includes data and metadata associated with the one or more trained ML models 180 and/or the one or more remote ML models 190 generating design objects 144 in response to prompts provided by the design exploration application 130. In some embodiments, the design history 182 includes a prompt history of records representing successive iterations of prompts and design objects 144 that a single ML model 180 generates in response to the iterations of prompts. Additionally or alternatively, the design history 182 includes design objects 144 independent of the prompts. For example, the design history 182 can include multiple design objects 144 that were generated by different ML models 180, 190 in response to the same prompt. In some embodiments, the prompt history includes records of feedback provided by the user for a given design object 144. In such instances, the server device 160 can use the prompt history portion of the design history 182 as training data to further train the one or more ML models 180. Additionally or alternatively, the design exploration application 130 can retrieve contents of the design history 182 and display the retrieved contents to the user via the GUI 120. For example, as discussed above, the design exploration application 130 can store a portion of the design history 182 and can generate one or more prompt cards 146, where the one or more prompt cards 146 are visualizations representing records included in the design history 182.

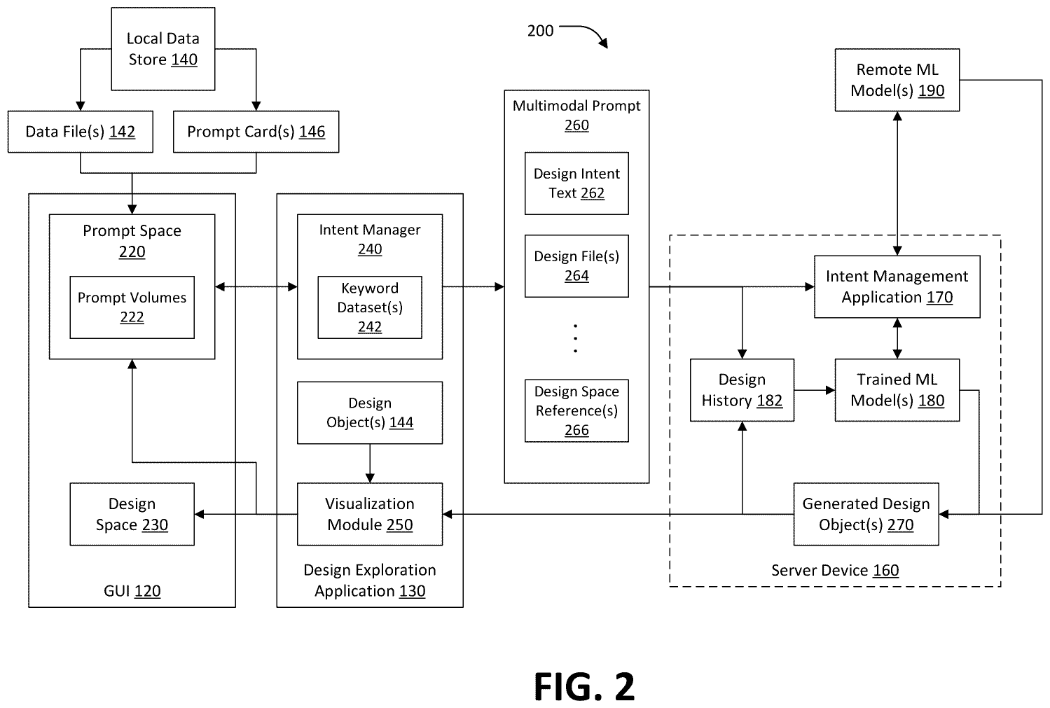

FIG. 2 is a more detailed illustration of the design exploration application 130 of FIG. 1, according to various embodiments. As shown, in some embodiments, the system 200 includes, without limitation, the GUI 120, the design exploration application 130, local data store 140, the one or more data files 142, the one or more prompt cards 146, the server device 160, the remote ML models 190, the and a multimodal prompt 260. The GUI 120 includes, without limitation, a prompt space 220 including one or more prompt volumes 222, and a design space 230. The design exploration application 130 includes, without limitation, an intent manager 240 including one or more keyword datasets 242, the one or more design objects 144, and a visualization module 250. The server device 160 includes, without limitation, the intent management application 170, the one or more trained models 180, the design history 182, and one or more generated design objects 270. The multimodal prompt 260 includes, without limitation, design intent text 262, one or more design files 264, and one or more design space references 266.

For explanatory purposes only, the functionality of the design exploration application 130 is described herein in the context of exemplar interactive and linear workflows used to generate the generated design object 270 in accordance with user-based design-related intentions expressed during the workflow. The generated design object 270 includes, without limitation, one or more images, wireframe models, geometries, and/or meshes for use a three-dimensional design, as well and any amount (including none) and/or types of associated metadata.

As persons skilled in the art will recognize, the techniques described herein are illustrative rather than restrictive and can be altered and applied in other contexts without departing from the broader spirit and scope of the inventive concepts described herein. For example, the techniques described herein can be modified and applied to generate any number prompt cards 146, and/or any number of generated design objects 270 associated with any target 3D object in a linear fashion, a nonlinear fashion, an iterative fashion, a non-iterative fashion, a recursive fashion, a non-recursive fashion, or any combination thereof during an overall process for generating and evaluating designs for that target 3D object. A target 3D object can include any number (including one) and/or types of target 3D objects and/or target 3D object components.

For example, in some embodiments, a generated design object 270 can be generated and displayed within the GUI 120 during a first iteration. In addition, the design exploration application 130 can generate and display a prompt card 146 representing a record of the interaction between the user and the trained ML model 180. Any portion (including all) of the prompt card 146 and/or the design object 270 can be selected via the GUI 120. A first multimodal prompt 260 can be set equal to the selected portion of the prompt card 146 and/or the generated design object 270 to recursively generate a second generated design object 270 during a second iteration. In the same or other embodiments, the design exploration application 130 can display and/or re-display any number of GUI elements, generate and/or regenerate any amount of data, or any combination thereof any number of times and/in any order while generating each new generated design object 270.

In operation, the visualization module 250 of the design exploration application 130 provides the prompt space 220 and the design space 230 via the GUI 120. The design exploration application 130 displays one or more prompt cards 146 retrieved from the local data store 140 in the prompt space 220 and/or displays portions of a 3D design in the design space 230. A user provides the contents for the multimodal prompt 260 via the prompt space 220. The design exploration application 130 processes the content to generate the multimodal prompt 260 and transmits the multimodal prompt 260 to the server device 160. The intent management application 170 identifies the modalities of the data included in the multimodal prompt 260 and identifies one or more trained ML models 180 and/or remote ML models 190 that have been trained to process the identified combination of modalities. The intent management application 170 inputs the multimodal prompt 260 into one or more of the identified ML models 180, 190. The ML models 180, 190 respond to the multimodal prompt 260 by generating one or more design objects 270. The visualization module 250 receives the one or more generated design objects 270 and displays the one or more generated design objects 270 in the prompt space 220 and/or the design space 230.

In various embodiments, the design space 230 is a virtual workspace that includes one or more renderings of design objects (e.g., geometries of the design objects 144 and/or the generated design objects 270) that form an overall 3D design. In some embodiments, the design space includes multiple design alternatives for the overall 3D design. For example, the design space 230 may graphically organize multiple 3D designs that include differing combinations of design objects 144, 270. In such instances, the user interacts with the GUI to navigate between design alternatives to quickly analyze tradeoffs between different design options, observe trends in design options, constrain the design space, select specific design options, and so forth.

The prompt space 220 is a panel or volume in which a user can generate prompts, such as the multimodal prompt 260 and/or the one or more prompt volumes 222. In some embodiments, the prompt space 220 is a panel, such as a window separate from the design space. Alternatively, in some embodiments, the prompt space 220 is a volume (e.g., a volumetric room) that displays one or more prompt cards 146. In some embodiments, the prompt space 220 is a volume that is overlayed over at least a portion of the design space 230 (e.g., a unified prompt space). In such instances, a user can invoke a prompt volume 222 and/or an input area for a multimodal prompt 260 at various locations within the design space 230. The user can also view one or more prompt cards 146 and locations within proximate to the overall 3D design within the design space 230 (e.g., along a virtual wall proximate to the overall 3D design).

The prompt volume 222 is a form of a prompt that executes operations within the boundaries of the volume. The prompt volume 222 is a volume within the design space 230 that is defined by a corresponding prompt definition that specifies how objects appear and/or behave within the boundaries of the prompt volume 222. The prompt volume 222 exerts a “sphere of influence” (e.g., a volume of influence based on the boundaries) within the defined boundaries such that modifications made to the associated prompt definition causes changes to design objects 144 within the boundaries. For example, the prompt definition enables the user to specify design intent text and/or non-textual inputs for objects that at least partially overlap the prompt volume 222. The prompt volume 222 a set of characteristics, including a spatial position (e.g., location and orientation), boundaries (defined via the textual definition or via user input within the prompt space 220), and shape (e.g., a sphere, a cuboid, a pyramid, an irregular 3D shape, etc.). In some embodiments, the prompt volume 222 includes weighted areas, weighted gradients, and/or linked prompt volumes (e.g., prompt volumes 222(1)-222(x)). In such instances, the linked prompt volumes 222(1)-222(x) include other overlapping prompt volumes and/or other prompt volumes linked in a hierarchy.

In various embodiments, when the user modifies the prompt volume 222, the prompt volume 222 executes by updating one or more design objects 144, 270 that are within the sphere of influence of the prompt volume 222. For example, upon detecting a change to the prompt definition, the prompt volume 222 can receive a newly generated design object 270 and add replace an existing design object 144 that is within the prompt volume 222. Additionally or alternatively, in some embodiments, the prompt volume 222 applies weighted values corresponding to the weighted areas and/or weighted gradients of the prompt volume 222. Upon executing the updates, the prompt volume 222 can cause the design exploration application 130 to generate a message indicating the change and “transmit” the message to other linked prompt volumes 222. In such instances, the prompt volumes 222 propagate changes among linked prompt volumes 222, which enables users to make modifications to multiple volumes within the design space 230 without applying global changes to the entire design space 230.

In various embodiments, the intent manager 240 determines the intent of inputs provided by the user. For example, the intent manager 240 can comprise a natural language (NL) processor that parses text provided by the user. Additionally or alternatively, the intent manager 240 can include processes audio data to identify words included in audio data and parse the identified words. In another example, the intent manager 240 detects inking within the prompt space 220 and/or gestural actions performed within the prompt space 220 (e.g., swiping away a prompt card 146). The intent manager 240 determines the intent of the user and causes the design exploration application 130 to respond based on the determined intent. For example, the intent manager can cause the design exploration application 130 to link two prompt cards 146(1)-146(2) based on determining that an inking within the prompt space 220 is proximate to the respective prompt cards. In another example, the intent manager 240 causes the design exploration application 130 to generate a multimodal prompt 260 based on the determined intent.

In various embodiments, the intent manager 240 identifies one or more keywords in design intent text. In some embodiments, the intent manager 240 includes one or more keyword datasets 242 that the intent manager 240 references when identifying the one or more keywords included in textual data. For example, the keyword datasets 242 can include, without limitation, a 3D keyword dataset that includes any number and/or types of 3D keywords, a customized keyword dataset that includes any number and/or types of customized keywords, and/or a user keyword dataset that includes any number and/or types of user keywords (e.g., words and/or phrases specified by a user). The keywords can comprise particular words or phrases (e.g., demonstrative pronouns, technical terms, referential terms, etc.) that are relevant to designing 3D objects. For example, a user can input a regular sentence (“I want a hinge to connect here”) within an input area within the prompt space 220. The intent manager identifies “hinge,” “connect,” and “here” as words relevant to the ML model 180, 190 generating a design object 270. In such instances, the intent manager 240 can update the prompt space 220 by highlighting the keywords, enabling the user to provide additional details (e.g., non-textual data) for inclusion in the multimodal prompt 260.

Additionally or alternatively, the intent manager 240 determines intent from one or more non-textual inputs. For example, the intent manager 240 can determine an intent of a gestural interactions (e.g., pinches, swipes, etc.) within the prompt space 220 and/or inked lines (e.g., annotations, connectors, cross-outs, circles, etc.) within the prompt space 220. In such instances, the design exploration application 130 can modify one or more prompt cards 146 in accordance with the determined intent.

In various embodiments, the visualization module 250 displays the design space and/or the prompt space 220 within via the GUI 120. In some embodiments, the visualization module 250 updates the prompt space 220 and/or the design space 230 based on inputs by the user and/or data received from the server device 160. For example, the visualization module 250 can initially respond to the user invoking a prompt via a hotkey or a marking menu within the prompt space 220 by displaying an input area to receive data to include in the multimodal prompt 260. When the user initially inputs a textual phrase, the visualization module 250 can respond to the intent manager 240 identifying one or more keywords by updating the input area highlight the keywords and/or display contextual input areas proximate to at least one keyword. In this manner, the design exploration application 130 iteratively receives multiple modalities of input data to include into the multimodal prompt 260.

In various embodiments, the design exploration application 130 receives textual and/or non-textual data to include in the multimodal prompt via the input areas included in the prompt space 220. When providing non-textual data, the user can retrieve stored data, such as one or more stored data files 142 (e.g., stored geometries, stored CAD files, audio recordings, stored sketches, etc.) from the local data store 140. Additionally or alternatively, the user can retrieve contents from the design history 182 and can add the contents into the input area. In such instances, the contents from the design history 182 is stored in one or more data files 142 that the user retrieves from the local data store 140. In another example, the user can select a portion of a prompt card 146 displayed within the prompt space 220. In such instances, the design exploration application 130 can extract the selected portion of the prompt card 146 and include the selected portion in the multimodal prompt 260.

The multimodal prompt 260 is a prompt that includes two or more modalities of data (e.g., textual data, image data, audio data, etc.) that specifies the design intent of the user. In various embodiments, the design exploration application 130 receives multiple types of data and builds the multimodal prompt 260 to include each of the multiple types of data. For example, a user can initially write design intent text 262 that refers to a sketch. The design exploration application 130 then receives a sketch (e.g., a stored sketch, a sketch included in a prompt card 146, and/or a sketch the user inputs into an input design area). Upon receiving the sketch, the design exploration application 130 can then generate the multimodal prompt 260 to include both the design intent text 262 and the sketch. In some embodiments, the multimodal prompt 260 can include multiple data inputs of the same modality. For example, the multimodal prompt 260 can include multiple design intent texts 262 (e.g., 262(1), 262(2), etc.) and/or multiple design files 264 (e.g., 264(1), 264(2), etc.).

The design intent text 262 includes textual data that describes the intent of the user. For example, the design intent text can include descriptions for characteristics of a target 3D design object (e.g., “a handle made of titanium”). In some embodiments, the design exploration application 130 generates design intent text 262 from a different type of data input. For example, the intent manager 240 can perform NL processing to identify words included in an audio recording. In such instances, the design exploration application 130 generates design intent text 262 that includes the identified words.

The design files 264 includes one or more files (e.g., CAD files, stored text, audio recordings, stored geometries, etc.) that the user adds to be included in the multimodal prompt 260. In some embodiments, the design files 264 can include textual data (e.g., textual descriptions, physical dimensions, etc.). In various embodiments, a user can add multiple design files 264 to include in the multimodal prompt 260. In some embodiments, the design exploration application 130 converts various types of data into the design files 264. For example, the user can record audio via the input area. In such instances, the design exploration application 130 can store audio recording as a design file 264. The design files 264 can include one or more modalities (e.g., textual data, video data, audio data, image data, etc.). In another example, the design exploration application 130 can extract a portion of a prompt card 146 selected by a user and include the selected portion as a design file 264.

In some embodiments, the design space references 266 can include one or more references to the prompt space 220 and/or the design space 230. For example, the user can input text that references a specific application state (e.g., “make the thing selected by the current tool lighter,” “generate a seat for the car in this view,” etc.). In such instances, the design exploration application 130 determines the application state the user is referencing. The design exploration application 130 can then include the reference in the multimodal prompt 260 as the design space reference 266.

In various embodiments, the intent management application 170 receives and processes the multimodal prompt 260 to identify the modalities of the contents of the multimodal prompt 260. For example, the intent management application 170 the modalities of the design intent text 262, the one or more design files 264, and/or the one or more design space references 266 included in the multimodal prompt 260. For example, the intent management application 170 can identify a combination of text, image, and video modalities included in the multimodal prompt. The intent management application 170 identifies at least one ML model 180, 190 that was trained with that combination of modalities and selects one of the identified ML models 180, 190. The intent management application 170 executes the selected ML model by inputting the multimodal prompt 260 into the selected ML model. The selected ML model generates a design object 270 in response to the multimodal prompt 260.In some embodiments, the server device includes the generated design object 270 in the design history 182. In such instances, the generated design object 270 is a portion of the design history 182 used as training data to train one or more trained ML models 180 (e.g., further training the selected ML model, training other ML models, etc.).

### Prompt Cards for Representing Interactions with an Artificial Intelligence Model

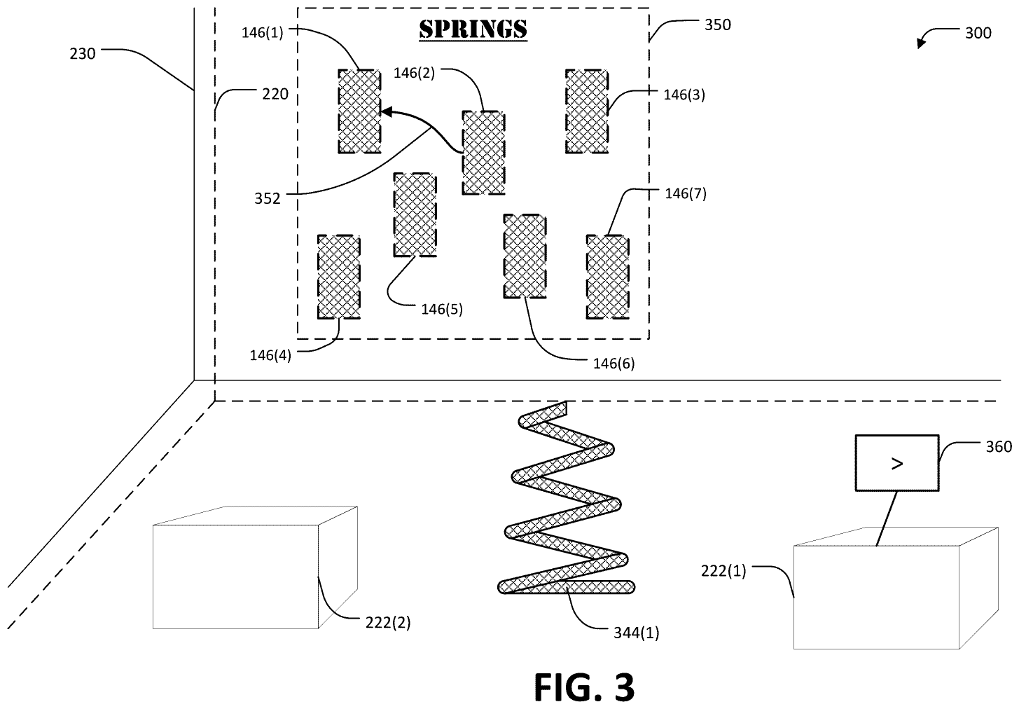

FIG. 3 is an exemplar illustration of the design space and the prompt space 220 of FIG. 2, according to various embodiments. As shown, the visualization 300 includes, without limitation, the prompt space 220, the design space 230, a plurality of prompt volumes 222 (e.g., 222(1), 222(2), etc.), a prompt input areas 360, a geometry 344(1) of a design object 144(1), and a prompt card grouping 350. The prompt card grouping 350 includes without limitation, a plurality of prompt cards 146 (e.g., 146(1)-146(7)), and an annotation 352.

In various embodiments, the visualization module 250 of the design exploration application 130 displays a visualization 300 of the design space 230 and the prompt space 220 via the GUI 120. As shown, the visualization 300 displays a unified prompt space, where the prompt space 220 is overlayed over the design space 230. In such instances, the design exploration application 130 can place the plurality of prompt cards 146 at various locations within the unified prompt space. Additionally or alternatively, the user can invoke a prompt anywhere within the design space 230.

The design space 230 is a volumetric space that displays one or more geometries 344 of design objects 144 that are part of a 3D design. The design space 230 can include two-dimensional (e.g., panels, textures, overlays, etc.) and/or three-dimensional content. In various embodiments, the design exploration application 130 enables the user to manipulate a camera within the design space 230 using one or more tools (not shown) to control the roll, pitch, yaw, zoom level, etc., of the camera. Additionally or alternatively, the design exploration application 130 includes controls to sketch images, create new geometries 344 and textures and/or edit existing geometries 344 of design objects 144. In various embodiments, the design space 230 can include multiple geometries 344 that combine to form an overall 3D design. For example, the design space 230 can include a plurality of components that combine to form an overall 3D design for a gearbox.

The prompt space 220 is a volume that displays one or more records included in the prompt history and enables the user to generate prompts that are usable to interact with the ML models 180, 190. In various embodiments, the prompt space 220 overlays at least a portion of the design space 230. Alternatively, in some embodiments, the prompt space 220 is a separate than the volume forming the design space 230. In various embodiments, the user can invoke a prompt (e.g., a prompt input area 360 and/or a prompt volume 222) via a hotkey or a marketing menu within the prompt space 220. For example, the user can select a tool (not shown) to draw the prompt volume 222(2). In another example, the user can invoke the prompt volume 222(1) and an associated prompt input area 360. In such instances, the user can add textual data to the prompt input area 360 to provide a prompt definition for the prompt volume 222(1). Additionally or alternatively, the user can press a hotkey to invoke the prompt input area 360 to provide a textual user input.

In various embodiments, the design exploration application 130 can display one or more prompt cards 146 within the prompt space 220. For example, as shown, the prompt space 220 includes a virtual wall on which the prompt card grouping 350 is displayed. In various embodiments, the design exploration application 130 filters and/or group prompt cards 146 based on criteria associated with the contents of the respective prompt card 146. In some embodiments, the local data store 140 stores one or more existing prompt cards 146. In such instances, the design exploration application 130 can retrieve one or more existing prompt cards 146 from the local data store 140 and display the existing prompt cards 146 in the prompt space 220. Additionally or alternatively, in some embodiments, the local data store 140 stores one or more records of the prompt history that have no corresponding prompt card. In such instances, the design exploration application 130 can retrieve the record from the prompt history and generate a new prompt card that includes at least the prompt (and a response) included in the record. The design exploration application 130 can then add the generated prompt card 146 to the prompt space 220.

In some embodiments, the user interacts with one or more of the prompt cards 146 directly. Additionally or alternatively, in some embodiments, the user interacts with the prompt cards 146 via interaction tools and/or gestural controls. For example, a user can select a brush and ink the annotation 352 showing a relationship between the prompt card 146(2) and the prompt card 146(1). In such instances, the design exploration application 130 detects the annotation 352 and uses the intent manager 240 to determine the intent of the user based on the annotation 352. The design exploration application 130 can respond to a determined intent of linkage by adding metadata linking the prompt card 146(1) to the prompt card 146(2).

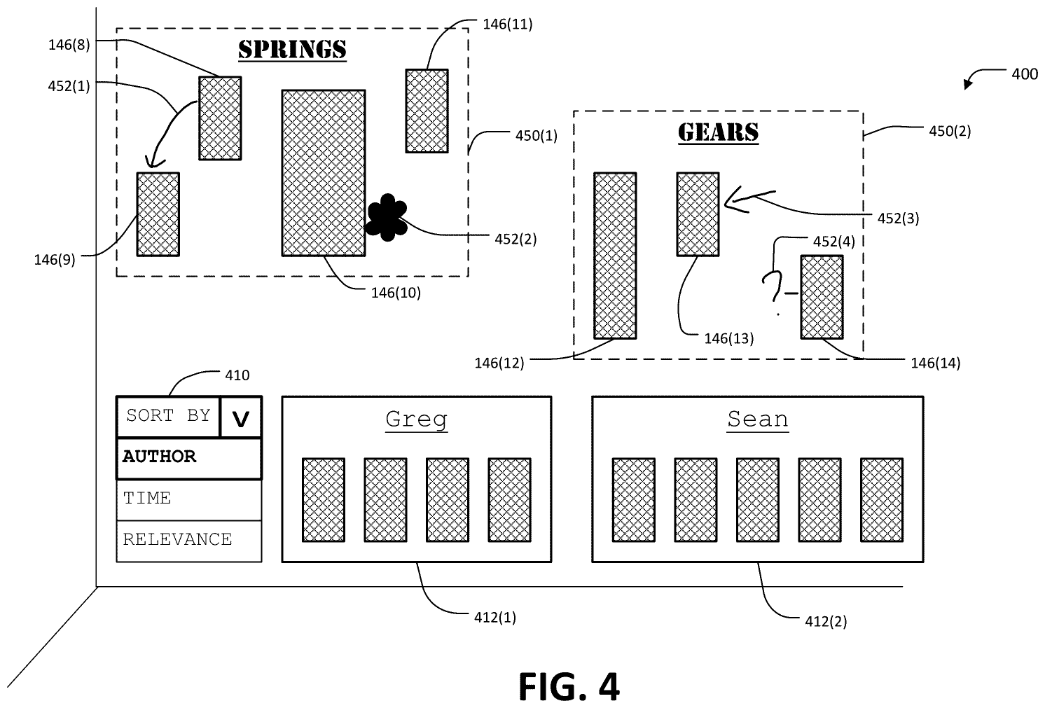

FIG. 4 is an exemplar illustration of prompt cards organized within the prompt space 220 of FIG. 2, according to various embodiments. As shown, the virtual wall 400 includes, without limitation, a plurality of user-defined prompt card groupings 450 (e.g., 450(1), 450(2)), a selection window 410, and selected prompt card groupings 412 (e.g., 412(1), 412(2)). The user-defined prompt card grouping 450(1) includes, without limitation, a plurality of prompt cards 146 (e.g., 146(8)-146(11)), and a plurality of annotations 452 (e.g., 452(1), 452(2)). The user-defined prompt card grouping 450(2) includes, without limitation, a plurality of prompt cards 146 (e.g., 146(12)-146(14)).

In operation, the design exploration application 130 via the GUI 120 displays the prompt space 220 as an interactive space in which the user can explore and interact with one or more prompt cards 146. For example, the GUI 120 can display an interactive space that includes one or more vertical partitions (e.g., virtual wall 400). In various embodiments, the design exploration application 130 generates one or more prompt cards 146 from a prompt history. A given prompt card 146 is a visual record of a portion of a series of interactions between a user and an ML model 180, 190. In some embodiments, the design exploration application 130 includes one or more tools (not shown) to explore and/or modify the prompt space 220. Such tools include navigational controls (e.g., traversal controls, zoom controls, etc.) and/or interaction tools (e.g., brushes for inking portions of the interactive space and/or the one or more prompt cards 146). The design exploration application 130 can arrange a set of prompt cards 146 on the virtual wall 400 and enable the user to ink the virtual wall 400 with one or more lines to indicate intent for interacting with one or more prompt cards 146 (e.g., groupings, selections, annotations, direct links, etc.).

In various embodiments, the design exploration application 130 generates and/or modifies the metadata associated with a given prompt card 146. For example, the metadata can include, without limitation information associated with the author, keywords, dates (e.g., time created, time modified, etc.), participants (e.g., user, team, type of ML model), input types, output types, and/or other descriptive details associated with the interaction between the user and a ML model 180, 190. In another example, the design exploration application 130 can determine keywords associated with images and/or 3D designs and add the keywords as metadata associated with the prompt card 146.

In some embodiments, the user can provide one or more inputs requesting that the design exploration application 130 order a set of prompt cards 146 based on a criterion (e.g., sortby=“author”). In such instances, the design exploration application 130 can group and/or arrange one or more prompt cards 146 using the criterion to generate the selected prompt card groupings 412, where each prompt card 146 included in the selected prompt card grouping 412 matches the criterion for the grouping (e.g., author=“Greg”).

In some embodiments, the user can manually filter and/or group one or more prompt cards 146 into the user-defined prompt card groupings 450. For example, the user can provide inputs to label the plurality of prompt cards 146(8)-146(11) as a user-defined prompt card grouping 450(1) of prompt cards 146 related to springs. In some embodiments, the user can perform gestural controls to modify the properties of a prompt card 146. For example, the user can manually move the prompt card 146(11) into the user-defined prompt card grouping 450(1). In such instances, the design exploration application 130 can add metadata to the prompt card 146(11) that associates the prompt card 146(11) to the user-defined prompt card grouping 450(1).

In various embodiments, the user can use various interaction tools to interact with one or more prompt cards 146 and/or the prompt space 220. In some embodiments, the design exploration application 130 provides tools to perform various camera operations (e.g., roll, pitch, yaw, zoom, etc.) to traverse through prompt space 220. Additional or alternatively, a user can select a brush and draw the annotation 452(1) showing a relationship between the prompt card 146(8) and the prompt card 146(9). In such instances, the design exploration application 130 detects the annotation 452(1) and uses the intent manager 240 to determine the intent based on the annotation 352. The design exploration application 130 can then, based on the determined intent, add metadata linking the prompt card 146(8) to the prompt card 146(9).

In some embodiments, the user can use the interaction tools to annotate individual prompt cards 146. For example, the user can use a brush to provide inking to the prompt space 220 that adds the annotations 452(2), 452(3), 452(4) to emphasize particular prompt cards 146 (e.g., the prompt cards 146(10), 146(13), 146(14)). In such instances, the design exploration application 130 can add keywords associated with the annotations (e.g., “high-quality”, “questionable”, “use this”, etc.) to reflect the intent of the inking.

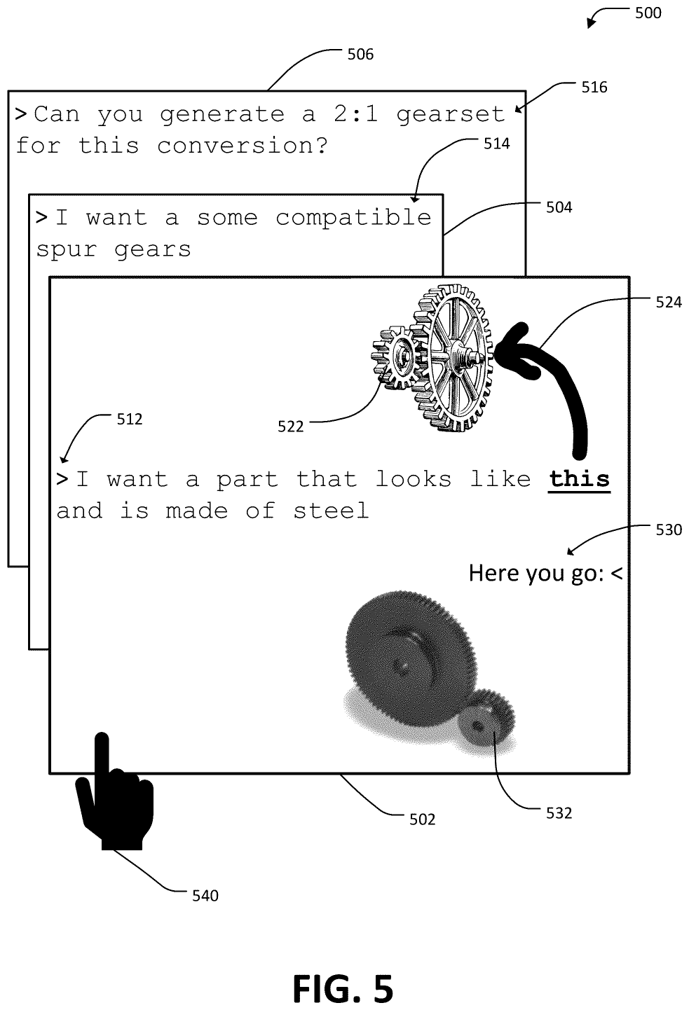

FIG. 5 is an exemplar illustration of multiple versions of a prompt arranged as prompt cards within the prompt space 220 of FIG. 2, according to various embodiments. As shown, the prompt card stack 500 includes, without limitation, prompt cards 502, 504, 506. The prompt card 502 includes a textual prompt 512, a sketch 522, a textual response 530, and a generated design object 532. The prompt card 504 includes, without limitation, a textual prompt 514. The prompt card 506 includes, without limitation, a textual prompt 516.

In various embodiments, the design exploration application 130 can display a group of related prompt cards 146 as a stack 500. For example, the design exploration application 130 can separate records of a single communication session between a user and an ML model 180, 190 into separate prompt cards 502-506, where each prompt card 502-506 represents the record of a single prompt provided to the ML model 180, 190 and a response that the ML model 180, 190 generated in response to the prompt. The design exploration application 130 can then add each prompt 502-506 into the prompt space 220 and arrange the prompt cards 502-506 as the prompt card stack 500. In some embodiments, the design exploration application 130 arranges the prompt card stack 500 in an order based on one or more criteria. For example, the design exploration application 130 can arrange prompt cards 502-506 representing the records of a single communication session in chronological order or reverse chronological order. Alternatively, in some embodiments, the design exploration application 130 can group other pluralities of prompt cards 146 into a stack. For example, the design exploration application 130 can group a set of two or more prompt cards 146 associated with a specific design object 144, 270 or a specific type of ML model 180, 190 into a stack. Additionally or alternatively, the design exploration application 130 can order the prompt cards 146 within the stack based on varying criteria (e.g., number of times copied, priority level, quality of response, number of annotations, number of linked prompt cards 146, etc.).

In some embodiments, the user can select a particular prompt card 502 within the prompt card stack 500 manually. For example, the user can use a cursor 540 to select the prompt card 502 from the prompt card stack 500. In such instances, the design exploration application 130 can rearrange the prompt cards 502-506 included in the prompt card stack 500 by moving the prompt card 502 to the top of the prompt card stack 500, where the entirety of the prompt card 502 is viewable within the prompt space 220. As shown, the top of the prompt card stack 500 partially obscures other prompt cards 504, 506. Each of the other prompt cards 504, 506 in the prompt card stack 500 are selectable via the cursor for full viewing at the top of the prompt card stack 500. In some embodiments, the user can input various gestural controls in the prompt space 220 to rearrange the prompt cards 502-506. For example, the user can select the prompt card 506 from the bottom of the prompt card stack 500 and drag the prompt card 506 to a different area of the prompt space 220 such that the prompt cards 502, 506 are fully viewable at different locations.

The prompt card 502 includes a multimodal prompt 260 including the textual prompt 512, the sketch 522, and an annotation 524 linking the sketch 522 to a keyword included in the textual prompt 512. In various embodiments, the design exploration application 130 initially generates a multimodal prompt 260 that includes multiple modalities of input. In such instances, the user can link non-textual inputs (e.g., the sketch 522) to map a keyword to the sketch 522. In such instances, the design exploration application 130 can store the prompt card 502 to include the sketch and the visual annotation 524.

The prompt card 502 also includes a response provided by an ML model 180, 190. For example, upon the design exploration application 130 transmitting the multimodal prompt 260, including the textual prompt 512 and the sketch 522, to the trained ML model 180 the design exploration application 130 receives a response from trained ML model 180. The response includes the textual response 530 and an image representing the generated design object 532. In such instances, the design exploration application 130 updates a record including both the prompt and the response, representing the interaction. The design exploration application 130 can then store the record as a part of a prompt history. Once the local data store 140 stores the record, the design exploration application 130 can then extract the record from the prompt history and generate the prompt card 502 to include the textual prompt 512, the sketch 522, the annotation 524, the textual response 530, and the design object 532.

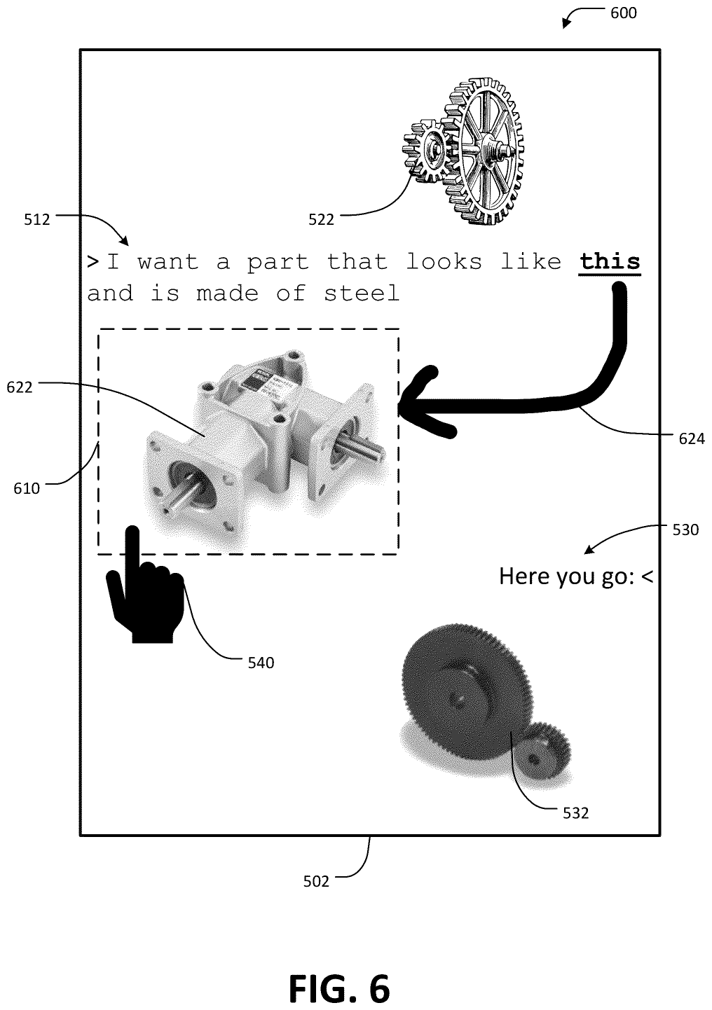

FIG. 6 is an exemplar illustration of a user interaction with a prompt card 502 within the prompt space 220 of FIG. 2, according to various embodiments. As shown, the visualization 600 of the interaction includes, without limitation, the prompt card 502, the cursor 540, and an annotation 624. The prompt card 502 includes, without limitation, the textual prompt 512, the sketch 522, the textual response 530, the generated design object 532, an input area 610, and an image 622.

In various embodiments, the design exploration application 130 adds an input area 610 to enable the user to add various inputs to modify the prompt card 502. For example, upon generating the prompt card 502, the design exploration application 130 can respond to a selection of the prompt card 502 by the cursor 540 by adding the input area 510 between the textual prompt 512 and the textual response 530. For example, the input area 610 can include a drag-and-drop area that enables users to perform drag-and-drop operations to add one or more stored files (e.g., data files 142 and/or design objects 144) to link to a keyword in the textual prompt 512. In some embodiments, the input area 610 also includes a file select icon that opens a file select window to enable the user to select one or more stored files via the file system of the client device 110, a sketch select icon that enables users to draw a sketch within the input area 610, and/or a record audio icon that enables users to record audio using the input area 610.

Upon adding non-textual input into the input area 610, the user can provide the annotation 624 to link the contents of the input area 610 to link to a keyword in the textual prompt 512. For example, the annotation 624 replaces the previous annotation 524 linking the sketch 522 to a keyword in the textual prompt 512 to the image 622 included in the input area 610. In such instances, upon detecting the annotation, the design exploration application 130 responds by generating a new multimodal prompt 260 including the textual prompt 512 and the image 622. Upon receiving a new response from the trained ML model 180, the design exploration application 130 can update the prompt card 502 by replacing the textual response 530 and the generated design object 532 with an updated the textual response (not shown) and a generated design object (not shown).

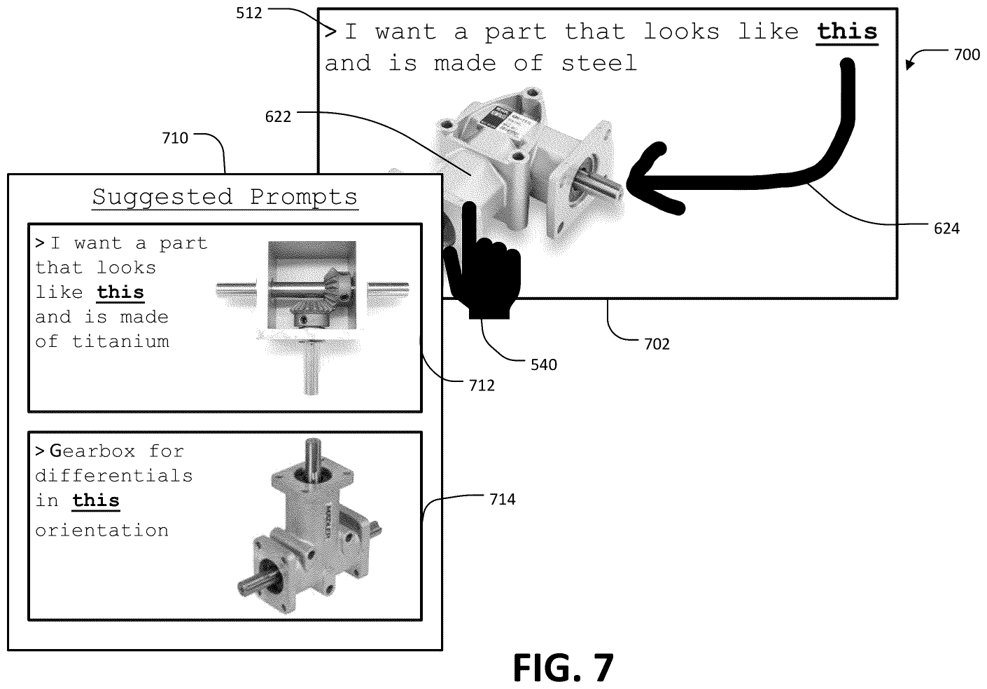

FIG. 7 is an exemplar illustration of a contextual suggestion window 710 generated within the prompt space 220 of FIG. 2, according to various embodiments. As shown, the visualization 700 includes, without limitation, the prompt card 502, the cursor 540, and the contextual suggestion window 710. The contextual suggestion window 710 includes, without limitations, a first candidate prompt card 712 and a second candidate prompt card 714.

In various embodiments, the design exploration application 130 can generate the contextual suggestion window 710 to aid a user in generating a new multimodal prompt 260 based on one or more prompt cards 146. The visualization module 250 can spatially place/locate the contextual suggestion window 710 within the prompt space 220 in an advantageous manner that promotes and improves the user's focus on the currently selected location in the prompt space 220. For example, if the user desires to use the record of an existing prompt to generate a new prompt to send to the ML models 180, 190, the user can invoke the contextual suggestion window 710 via a predetermined hotkey input. Alternatively, in some embodiments, the user moves the cursor 540 such that the cursor 540 hovers over a particular portion of the prompt card 702. In such instances, the design exploration application 130 can detect the hovering as a user input indicating an interaction with the prompt card 702. In such instances, the design exploration application 130 can respond by generating the contextual suggestion window 710 at a location proximate to the cursor 540.

In various embodiments, the design exploration application 130 can retrieve a set of frequently used prompt cards 146 to populate the contextual suggestion window 710. For example, the design exploration application 130 can select a subset of prompt cards 146 based on criteria such as the history of the user (e.g., the prompt history, the design history 182, historical data of exploration within the prompt space 220, etc.), the prompt history of a team of users, the prompt of a company, and so forth. Additionally or alternatively, the design exploration application 130 can use other criteria, such as other prompt cards 146 are proximate to the cursor (e.g., within a threshold distance of the cursor within the prompt space 220), and/or properties of the text or object being selected (e.g., keywords, design properties, etc.). Upon identifying a particular keyword or object, the design exploration application 130 identifies one or more existing prompt cards that satisfy the criteria. The design exploration application 130 can also filter and/or sort the identified prompt cards and include a subset of the identified prompt cards in the contextual suggestion window 710.

For example, the cursor 540 is hovering over an image 622 of a bevel gearbox. The design exploration application 130 can respond to the hovering by generating the contextual suggestion window 710 and include candidate prompt cards 712, 714 that are related to bevel gearboxes. In such instances, the user can select one of the candidate prompt cards 712, 714 and use the selected prompt card as the basis for a new multimodal prompt 260.

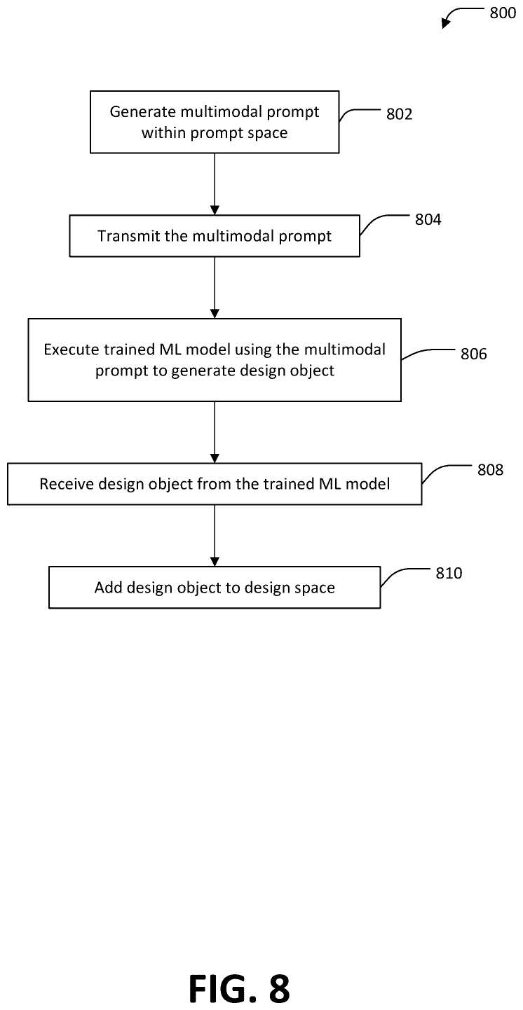

FIG. 8 sets forth a flow diagram of method steps for generating 3D objects, according to various embodiments. Although the method steps are described with reference to the systems of FIGS. 1-7 and 11, persons skilled in the art will understand that any system configured to implement the method steps, in any order, falls within the scope of the embodiments.

As shown, a method 800 begins at step 802, where the design exploration application 130 generates a multimodal prompt 260 within the prompt space 220. In various embodiments, the design exploration application 130 responds to a user input by generating a prompt within the prompt space 220. In some embodiments, the prompt space 220 at least partially overlays the design space 230. In such instances, the user can invoke the multimodal prompt 260 at various locations within the design space 230. In some embodiments, the design exploration application 130 generates a prompt input area 360 for the multimodal prompt 260 for the user to enter data, such as text and/or non-textual data. Additionally or alternatively, in some embodiments, the design exploration application 130 may generate a prompt volume within the design space 230.

At step 804, the design exploration application 130 transmits the multimodal prompt 260. In various embodiments, the design exploration application 130 generates the multimodal prompt 260 and transmits the multimodal prompt 260 to the server device 160 for input into one or more ML models 180, 190. In various embodiments, the design exploration application 130 generates the multimodal prompt 260 to include a plurality of data types, where the multimodal prompt 260 includes at least two modalities. For example, the design exploration application 130 can generate a multimodal prompt 260 that includes at least design intent text 262 and at least one design file 264 comprising video data.

At step 806, the design exploration application 130 executes a trained ML model 180, 190 using the multimodal prompt 260 to generate a design object 270. In various embodiments, the design exploration application 130 causes the server device 160 to execute at least one trained ML model 180, 190 on the multimodal prompt 260 to generate the design object 270. In various embodiments, one or more trained ML models 180 local to the server device 160 and/or one or more remote ML devices 190 are trained using multimodal prompts. In such instances, the intent management application 170 operating on the server device 160 can identify the combination of modalities included in the multimodal prompt 260 and selects an applicable ML model 180, 190 that was trained using the identified combination of modalities. The intent management application 170 inputs the multimodal prompt 260 into the selected ML model 180, 190.

At step 808, the design exploration application 130 receives the generated design object 270 from the trained ML model 180, 190. In various embodiments, the server device 160 receives the generated design object 270 from the selected ML model 180, 190 and transmits the generated design object 270 to the client device 110. In such instances, the design exploration application 130 receives the generated design object 270 and causes the client device 110 to store the generated design object 270 in the local data store 140.

At step 810, the design exploration application 130 adds the generated design object 270 to the design space 230. In various embodiments, the visualization module 250, upon receiving the generated design object 270, adds the generated design object to a location in the design space 230 for viewing via the GUI 120. In some embodiments, the prompt space 220 is separate from the design space 230. In such instances, the visualization module 250 can display the generated in the prompt space 220 in lieu of or in addition to displaying the generated design object 270 in the design space 230.

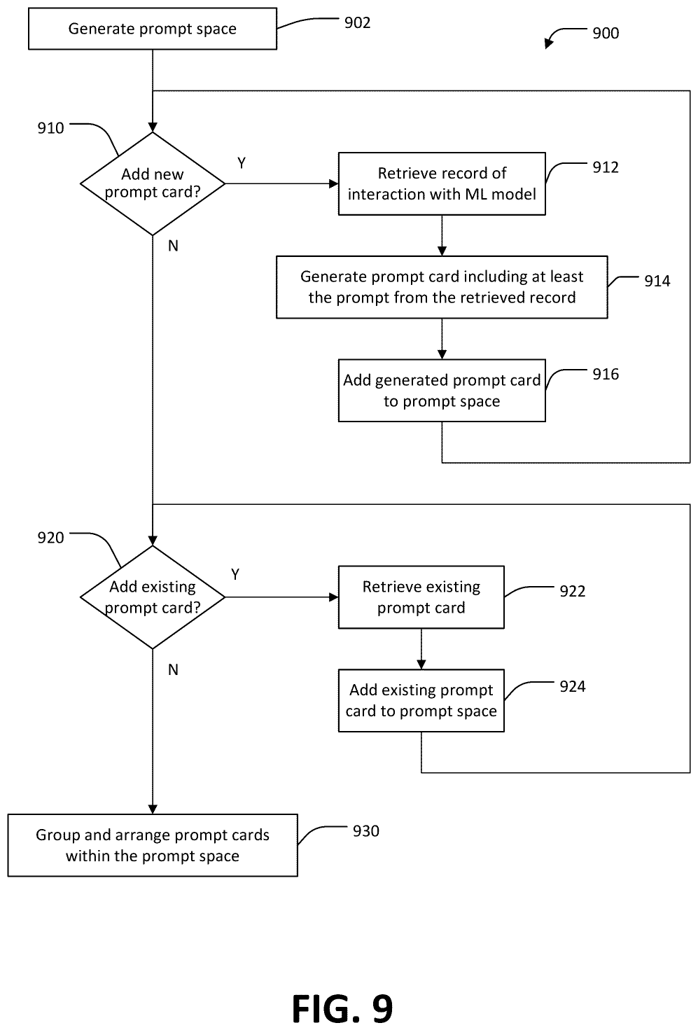

FIG. 9 sets forth a flow diagram of method steps for displaying prompt cards within a prompt space, according to various embodiments. Although the method steps are described with reference to the systems of FIGS. 1-7 and 11, persons skilled in the art will understand that any system configured to implement the method steps, in any order, falls within the scope of the embodiments.

A method 900 begins at step 902, where the design exploration application 130 generates the prompt space 220. In various embodiments, the design exploration application 130 generates the prompt space 220 as an overlay over a design space 230, or as a separate volumetric room. The prompt space 220 is a volume in which a user can generate prompts, such as the multimodal prompt 260. The prompt space 220 also displays one or more prompt cards 146 generates prompt cards 146 from a prompt history, where a given prompt card 146 is a visual record of a portion of interactions between a user and an ML model 180, 190. When the prompt space 220 is overlayed over the design space 230, a user can invoke an input area for a multimodal prompt 260 at various locations within the design space 230. The design exploration application 130 can place the plurality of prompt cards 146 at various locations within the unified prompt space. Additionally or alternatively, the user can invoke a prompt anywhere within the design space 230. In such instances, the user can also view one or more prompt cards 146 and locations within proximate to the overall 3D design (e.g., along a virtual wall proximate to the overall 3D design).

At step 910, the design exploration application 130 determines whether to add a new prompt card 146. In various embodiments, the design exploration application 130 determines whether the local data store 140 stores one or more records of the prompt history that have no corresponding prompt card. In such instances, the design exploration application 130 can retrieve the record from the prompt history and generate a new prompt card. When the design exploration application 130 determines that a new prompt card 146 is to be generated from a record, the design exploration application 130 proceeds to step 912; otherwise, the design exploration application 130 determines not to generate a new prompt card 146 and proceeds to step 920.

At step 912, the design exploration application 130 retrieves a record of an interaction with the ML model 180, 190. In various embodiments, in some embodiments, the local data store 140 stores one or more records of the prompt history. In various embodiments, the design exploration application 130 retrieves a record from the prompt history. At step 914, the design exploration application 130 generates a prompt card including at least the prompt from the retrieved record. In various embodiments, the new prompt card 146 includes at least a prompt included in the interaction. In some embodiments, the new prompt card 146 also includes a response from the ML model 180, 190 that is included in the record.

At step 916, the design exploration application 130 adds the generated prompt card 146 to the prompt space 220. In various embodiments, upon generating the new prompt card 146, the design exploration application 130 can then add the generated prompt card 146 to the prompt space 220. For example, the design exploration application 130 adds the new prompt card 146 at a location in the prompt space 220 includes a virtual wall on which the new prompt card 146 is displayed.

At step 920, the design exploration application 130 determines whether to add an existing prompt card 146 to the prompt space 220. In various embodiments, the design exploration application 130 filters and/or group prompt cards 146 based on criteria associated with the contents of the respective prompt card 146. When the design exploration application 130 determines to add an existing prompt card 146, the design exploration application 130 proceeds to step 922; otherwise,, the design exploration application 130 determines not to add an existing prompt card 146 and proceeds to step 930.

At step 922, the design exploration application 130 retrieves an existing prompt card 146 from the local data store 140. In some embodiments, the local data store 140 stores one or more existing prompt cards 146. In such instances, the design exploration application 130 can retrieve an existing prompt cards 146 from the local data store 140. At step 924, the design exploration application 130 adds the existing prompt card 146 to the prompt space 220. For example, the design exploration application 130 adds the existing prompt card 146 at a location in the prompt space 220 includes a virtual wall on which the existing prompt card 146 is displayed.

At step 930, the design exploration application 130 groups and arranges the prompt cards 146 within the prompt space 220. In various embodiments, the design exploration application 130 groups and/or arranges the prompt cards 146 in the prompt space 220 based on criteria associated with the contents of the respective prompt card. For example, the user can provide one or more inputs requesting that the design exploration application 130 order a set of prompt cards based on a criterion (e.g., sortby=“author”). In such instances, the design exploration application 130 can group and/or arrange one or more prompt cards 146 using the criterion to generate selected prompt card groupings 412, where each prompt card 146 included in selected prompt card grouping 412 matches the criterion for the grouping (e.g., author=“Greg”). In some embodiments, the user can manually filter and group one or more prompt cards 146 into user-defined prompt card groupings 450. In some embodiments, the user can perform gestural controls to modify the properties of a prompt card 146. For example, the user can manually move a prompt card 146 into a user-defined prompt card grouping 450. In such instances, the design exploration application 130 can add metadata to the prompt card 146 to associate the prompt card 146 to the user-defined prompt card grouping 450.

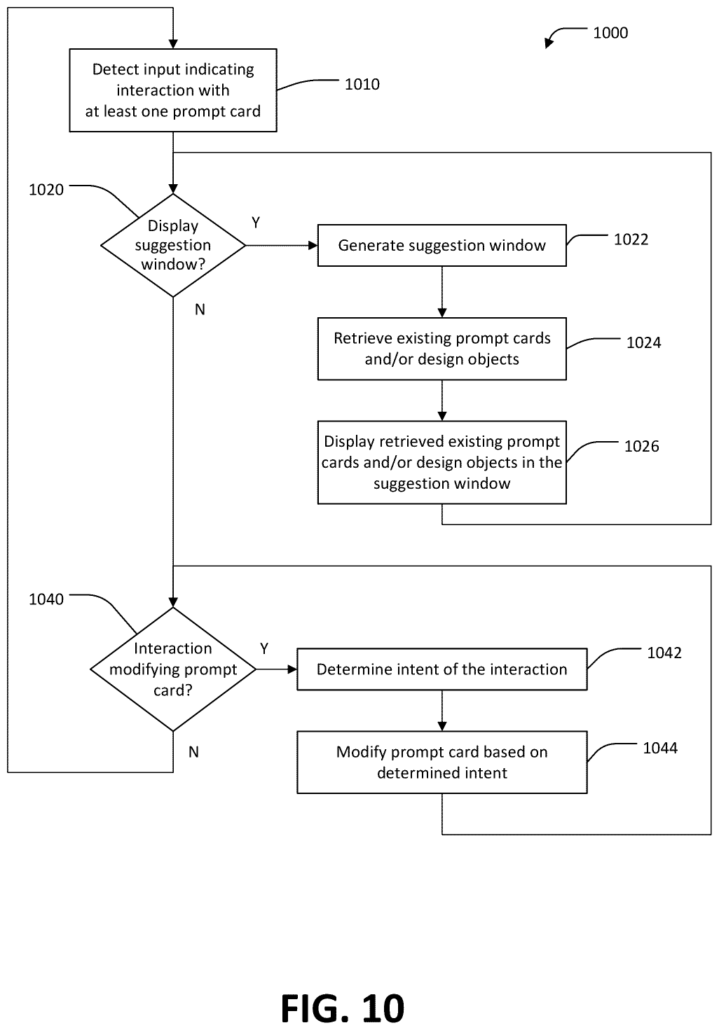

FIG. 10 sets forth a flow diagram for responding to interactions with a prompt card, according to various embodiments. Although the method steps are described with reference to the systems of FIGS. 1-7 and 11, persons skilled in the art will understand that any system configured to implement the method steps, in any order, falls within the scope of the embodiments.

A method 1000 begins at step 1010, where the design exploration application 130 detects an input indicating an interaction with at least one prompt card 146. In various embodiments, the user can use various interaction tools to interact with one or more prompt cards 146 and/or the prompt space 220. In some embodiments, the design exploration application 130 provides tools to perform various camera operations (e.g., roll, pitch, yaw, zoom, etc.) to traverse through prompt space 220. Additionally or alternatively, a user can select a brush and draw the annotation 452(1) showing a relationship between the prompt card 146(8) and the prompt card 146(9).

At step 1020, the design exploration application 130 determines whether to display a contextual suggestion window 710. In various embodiments, the design exploration application 130 can generate the contextual suggestion window 710 to aid a user in generating a new multimodal prompt 260 based on one or more prompt cards 146. For example, the user can invoke the contextual suggestion window 710 via a predetermined hotkey input. Alternatively, in some embodiments, the user moves the cursor 540 such that the cursor 540 hovers over a particular portion of a prompt card 146, 702. When the design exploration application 130 determines that the input indicates that the contextual suggestion window 710 is to be displayed, the design exploration application 130 proceeds to step 1022; otherwise, the design exploration application 130 proceeds to step 1040.

At step 1022, the design exploration application 130 generates the contextual suggestion window 710. In various embodiments, the design exploration application 130 spatially places/locates the contextual suggestion window 710 within the prompt space 220 based on the location of the cursor 540 when invoking the contextual suggestion window 710. In this manner, the contextual suggestion window 710 is placed in an advantageous manner that promotes and improves the user's focus on the currently selected location in the prompt space 220. For example, the design exploration application 130 can detect the cursor 540 hovering over a particular portion of the prompt card 702. In such instances, the design exploration application 130 can respond by generating the contextual suggestion window 710 at a location proximate to the cursor 540.

At step 1024, the design exploration application 130 retrieves one or more existing prompt cards 146 and/or one or more design objects 144 from the local data store 140. In various embodiments, the design exploration application 130 retrieves a set of frequently used prompt cards 146 to populate the contextual suggestion window 710. For example, the design exploration application 130 can select a subset of prompt cards 146 based on criteria such as the history of the user (e.g., the prompt history, the design history 182, historical data of exploration within the prompt space 220, etc.), the prompt history of a team of users, the prompt of a company, and so forth. Additionally or alternatively, the design exploration application 130 can use other criteria, such as other prompt cards 146 are proximate to the cursor (e.g., within a threshold distance of the cursor within the prompt space 220), and/or properties of the text or object being selected (e.g., keywords, design properties, etc.). Upon identifying a particular keyword or object, the design exploration application 130 identifies one or more existing prompt cards that satisfy the criteria.

At step 1026, the design exploration application 130 displays the retrieved existing prompt cards 146 and/or the retrieved design objects 144 in the contextual suggestion window 710. In various embodiments, the design exploration application 130 also filters and/or sort the identified prompt cards and include a subset of the identified prompt cards in the contextual suggestion window 710. For example, the design exploration application 130 can respond to the cursor 540 hovering over an image of a bevel gearbox by generating the contextual suggestion window 710 and including candidate prompt cards 712, 714 that are related to bevel gearboxes. In such instances, the user can select one of the candidate prompt cards 712, 714 and use the selected prompt card as the basis for a new multimodal prompt 260.

At step 1040, the design exploration application 130 determines whether the interaction modifies at least one prompt card 146. In various embodiments, the user can use the interaction tools to annotate individual prompt cards 146. For example, the user can use a brush to provide inking that adds annotations 452(2), 452(3), 452(4) to emphasize particular prompt cards 146 (e.g., the prompt cards 146(10), 146(13), 146(14)). In such instances, the design exploration application 130 can add keywords associated with the annotations (e.g., “high-quality”, “questionable”, “use this”, etc.). Additionally or alternatively, the user can perform a gestural interaction indicating a change to a prompt card 146. When the design exploration application 130 determines that the interaction indicates a modification to an existing prompt card 146, the design exploration application 130 proceeds to step 1042. Otherwise, the design exploration application 130 returns to step 1010.

At step 1042, the design exploration application 130 determines the intent of the detected interaction. In various embodiments, the design exploration application 130 detects an input as an interaction within the prompt space 220 (e.g., an inking of an annotation on a portion of the prompt space 220, a gestural interaction in the prompt space 220, etc.) and uses the intent manager 240 to determine the intent of the interaction. For example, a user can select a brush and draw the annotation 452(1) showing a relationship between the prompt card 146(8) and the prompt card 146(9). In such instances, the design exploration application 130 detects the annotation 452(1) and uses the intent manager 240 to determine the intent to link the prompt cards 146(8), 146(9) based on the annotation 352.

At step 1044, the design exploration application 130 modifies the prompt card based on the determined intent. In various embodiments, the design exploration application 130 modifies one or more prompts and/or responses in a given prompt card 146 based on the determined intent. In some embodiments, the design exploration application 130 modifies metadata associated with one or more prompt cards 146 in accordance with the determined intent. Following the above example, the design exploration application 130 can, based on the determined intent to link the prompt cards 146(8), 146(9), add metadata linking the prompt card 146(8) to the prompt card 146(9). In another example, For example, upon generating the prompt card 502, the design exploration application 130 can respond to a selection of a prompt card 502 by adding an input area 610, such as a drag-and-drop area that enables users to perform drag-and-drop operations to add one or more stored files (e.g., data files 142 and/or design objects 144) to link to a keyword in a textual prompt.

### System Implementation

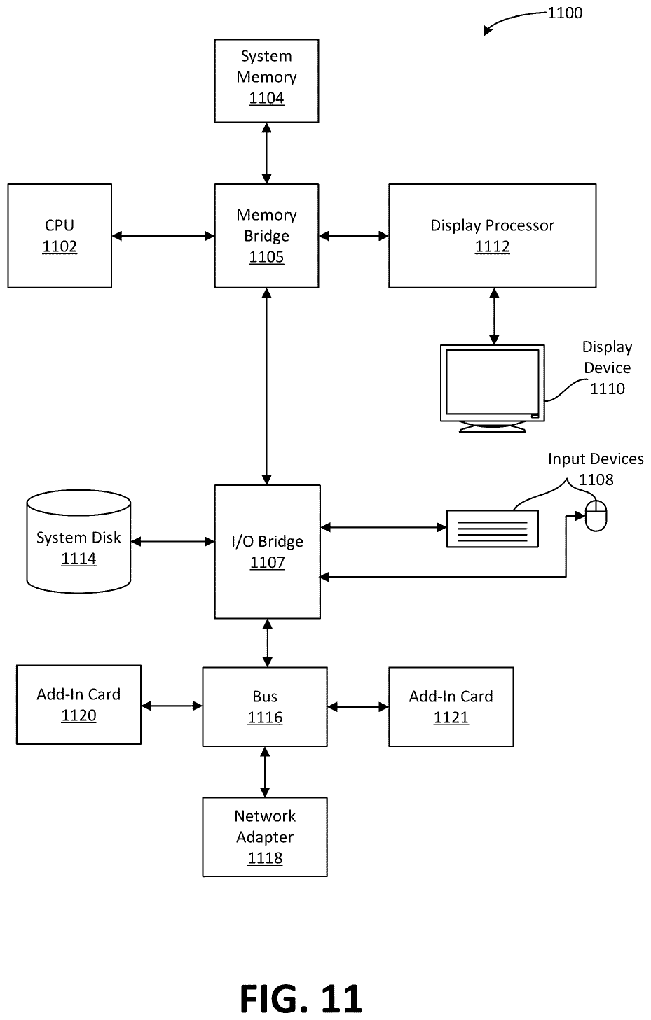

FIG. 11 depicts one architecture of a system 1100 within which the various embodiments may be implemented. This figure in no way limits or is intended to limit the scope of the present disclosure. In various implementations, system 1100 may be an augmented reality, virtual reality, or mixed reality system or device, a personal computer, video game console, personal digital assistant, mobile phone, mobile device, or any other device suitable for practicing one or more embodiments of the present disclosure. Further, in various embodiments, any combination of two or more systems 1100 may be coupled together to practice one or more aspects of the present disclosure.

As shown, system 1100 includes a central processing unit (CPU) 1102 and a system memory 1104 communicating via a bus path that may include a memory bridge 1105. CPU 1102 includes one or more processing cores, and, in operation, CPU 1102 is the master processor of system 1100, controlling and coordinating operations of other system components. System memory 1104 stores software applications and data for use by CPU 1102. CPU 1102 runs software applications and optionally an operating system. Memory bridge 1105, which may be, e.g., a Northbridge chip, is connected via a bus or other communication path (e.g., a HyperTransport link) to an I/O (input/output) bridge 1107. I/O bridge 1107, which may be, e.g., a Southbridge chip, receives user input from one or more user input devices 1108 (e.g., keyboard, mouse, joystick, digitizer tablets, touch pads, touch screens, still or video cameras, motion sensors, and/or microphones) and forwards the input to CPU 1102 via memory bridge 1105.

A display processor 1112 is coupled to memory bridge 1105 via a bus or other communication path (e.g., a PCI Express, Accelerated Graphics Port, or HyperTransport link); in one embodiment display processor 1112 is a graphics subsystem that includes at least one graphics processing unit (GPU) and graphics memory. Graphics memory includes a display memory (e.g., a frame buffer) used for storing pixel data for each pixel of an output image. Graphics memory can be integrated in the same device as the GPU, connected as a separate device with the GPU, and/or implemented within system memory 1104.

Display processor 1112 periodically delivers pixels to a display device 1112 (e.g., a screen or conventional CRT, plasma, OLED, SED or LCD based monitor or television). Additionally, display processor 1112 may output pixels to film recorders adapted to reproduce computer generated images on photographic film. Display processor 1112 can provide display device 1110 with an analog or digital signal. In various embodiments, one or more of the various graphical user interfaces set forth in Appendices A-J, attached hereto, are displayed to one or more users via display device 1110, and the one or more users can input data into and receive visual output from those various graphical user interfaces.

A system disk 1114 is also connected to I/O bridge 1107 and may be configured to store content and applications and data for use by CPU 1102 and display processor 1112. System disk 1114 provides non-volatile storage for applications and data and may include fixed or removable hard disk drives, flash memory devices, and CD-ROM, DVD-ROM, Blu-ray, HD-DVD, or other magnetic, optical, or solid state storage devices.

A switch 1116 provides connections between I/O bridge 1107 and other components such as a network adapter 1118 and various add-in cards 1120 and 1121. Network adapter 1118 allows system 1100 to communicate with other systems via an electronic communications network, and may include wired or wireless communication over local area networks and wide area networks such as the Internet.

Other components (not shown), including USB or other port connections, film recording devices, and the like, may also be connected to I/O bridge 1107. For example, an audio processor may be used to generate analog or digital audio output from instructions and/or data provided by CPU 1102, system memory 1104, or system disk 1114. Communication paths interconnecting the various components in FIG. 1 may be implemented using any suitable protocols, such as PCI (Peripheral Component Interconnect), PCI Express (PCI-E), AGP (Accelerated Graphics Port), HyperTransport, or any other bus or point-to-point communication protocol(s), and connections between different devices may use different protocols, as is known in the art.

In one embodiment, display processor 1112 incorporates circuitry optimized for graphics and video processing, including, for example, video output circuitry, and constitutes a graphics processing unit (GPU). In another embodiment, display processor 1112 incorporates circuitry optimized for general purpose processing. In yet another embodiment, display processor 1112 may be integrated with one or more other system elements, such as the memory bridge 1105, CPU 1102, and I/O bridge 1107 to form a system on chip (SoC). In still further embodiments, display processor 1112 is omitted and software executed by CPU 1102 performs the functions of display processor 1112.

Pixel data can be provided to display processor 1112 directly from CPU 1102. In some embodiments of the present disclosure, instructions and/or data representing a scene are provided to a render farm or a set of server computers, each similar to system 1100, via network adapter 1118 or system disk 1114. The render farm generates one or more rendered images of the scene using the provided instructions and/or data. These rendered images may be stored on computer-readable media in a digital format and optionally returned to system 1100 for display. Similarly, stereo image pairs processed by display processor 1112 may be output to other systems for display, stored in system disk 1114, or stored on computer-readable media in a digital format.

Alternatively, CPU 1102 provides display processor 1112 with data and/or instructions defining the desired output images, from which display processor 1112 generates the pixel data of one or more output images, including characterizing and/or adjusting the offset between stereo image pairs. The data and/or instructions defining the desired output images can be stored in system memory 1104 or graphics memory within display processor 1112. In an embodiment, display processor 1112 includes 3D rendering capabilities for generating pixel data for output images from instructions and data defining the geometry, lighting shading, texturing, motion, and/or camera parameters for a scene. Display processor 1112 can further include one or more programmable execution units capable of executing shader programs, tone mapping programs, and the like.

Further, in other embodiments, CPU 1102 or display processor 1112 may be replaced with or supplemented by any technically feasible form of processing device configured process data and execute program code. Such a processing device could be, for example, a central processing unit (CPU), a graphics processing unit (GPU), an application-specific integrated circuit (ASIC), a field-programmable gate array (FPGA), and so forth. In various embodiments any of the operations and/or functions described herein can be performed by CPU 1102, display processor 1112, or one or more other processing devices or any combination of these different processors.

CPU 1102, render farm, and/or display processor 1112 can employ any surface or volume rendering technique known in the art to create one or more rendered images from the provided data and instructions, including rasterization, scanline rendering REYES or micropolygon rendering, ray casting, ray tracing, image-based rendering techniques, and/or combinations of these and any other rendering or image processing techniques known in the art.

In other contemplated embodiments, system 1100 may be a robot or robotic device and may include CPU 1102 and/or other processing units or devices and system memory 1104. In such embodiments, system 1100 may or may not include other elements shown in FIG. 1. System memory 1104 and/or other memory units or devices in system 1100 may include instructions that, when executed, cause the robot or robotic device represented by system 1100 to perform one or more operations, steps, tasks, or the like.

It will be appreciated that the system shown herein is illustrative and that variations and modifications are possible. The connection topology, including the number and arrangement of bridges, may be modified as desired. For instance, in some embodiments, system memory 1104 is connected to CPU 1102 directly rather than through a bridge, and other devices communicate with system memory 1104 via memory bridge 1105 and CPU 1102. In other alternative topologies display processor 1112 is connected to I/O bridge 1107 or directly to CPU 1102, rather than to memory bridge 1105. In still other embodiments, I/O bridge 1107 and memory bridge 1105 might be integrated into a single chip. The particular components shown herein are optional; for instance, any number of add-in cards or peripheral devices might be supported. In some embodiments, switch 1116 is eliminated, and network adapter 1118 and add-in cards 1120, 1121 connect directly to I/O bridge 1107.

In sum, the disclosed techniques can be used to generate 2D or 3D designs in a design space via a prompt history organized in a prompt space in a GUI of a design exploration application. The prompt space can be used to perform one or more iterations of (1) entering user inputs and submitting prompts to an AI model and (2) receiving responses from the AI model. The prompt space also enables a user to explore the prompt history and use portions of the prompt history to perform further actions in the prompt space or the design space. For example, the user can select designs from the prompt history for use in the design space, or select prompts from the prompt history to generate additional prompts to input into an AI model.

In various embodiments, the prompt space overlaps with the design space, allowing the user to navigate through a single three-dimensional space and reference the prompt history when generating an overall design. Alternatively, in some embodiments, the prompt space is separate from the design space, where the design exploration application displays the prompt history without displaying the overall design so that the user can explore and navigate the prompt space without visual clutter. For example, the user can use navigation tools to travel within a 3D prompt space to review an arrangement of multiple prompts to AI models and responses from the AI models.

The design exploration application adds one or more prompt cards to the prompt space. Each prompt card is a visual representation of a portion of the prompt history; each prompt card includes at least one prompt provided to an AI model and at least one response from the AI model. In some embodiments, the prompt card includes a multimodal prompt that has at least two modalities to input into the AI model, such as text, audio, sketches, and/or references to the design space (e.g., a camera view of a portion of the design space). In some embodiments, a prompt card includes an image or 3D object generated by the AI model. The design exploration application can filter, group, and/or arrange prompt cards within the prompt space based on criteria, such as author, team (e.g., specific group of authors), object type, date generated, and/or keywords. Additionally or alternatively, in some embodiments, the design exploration application allows a user to manually arrange the prompt cards within the prompt space.

The user can interact with portions of the prompt card, such as by editing the prompt card, generating additional prompts from the prompt card, and/or selecting 3D objects included in the prompt card. For example, the user can add annotations and/or perform gestures within the prompt space to link two separate prompt cards together. The design exploration application responds to the annotations and/or gestures by generating a new prompt based on the contents of the respective prompt cards. In another example, the user can modify a prompt card by linking a portion of a textual prompt to a non-textual input that is not included in the prompt card, such as a 3D object included in a separate prompt card. In some embodiments, the design exploration application displays a contextual menu of related prompt cards based on a selected portion of a prompt card. In such instances, the user can select a prompt card displayed in the contextual menu and modify the selected prompt card to generate a new prompt. For example, the design exploration application can display the contextual menu as a window within the prompt space proximate to the location of a selected 3D object. The user can then select a suggested prompt card listed in the contextual menu and modify the contents of the selected prompt card to generate a new prompt to input into the AI model.

At least one technical advantage of the disclosed techniques relative to the prior art is that the disclosed techniques generate separate cards representing separate and distinct prompt histories for separate and distinct interactions with an AI model within a prompt space. In this regard, in response to a user request to view prompt histories that are associated with certain criteria, such as authors, a specific AI model, or a selected 3D object, a design exploration application displays the separate interactions as distinct cards within a navigable 3D space. Each of the cards can be moved, linked, and modified by the user. Further, the prompts are selectable for generating new prompts for the AI model, and 3D objects are selectable for inclusion in an overall design within a design space. Accordingly, with the disclosed techniques, the design exploration application can provide many separate and distinct prompt histories within a 3D space in a manner that a user can easily navigate and interact with the separate and distinct prompt histories. Such techniques allow the user to easily reference and retrieve information from previous interactions with the AI model, reducing the number of times the user needs to interact with AI model to produce desired 3D objects. Further, such techniques enable the design exploration application to display generated 3D designs as part of a prompt history in a manner that is easily searchable and readable to the user. These technical advantages provide one or more technological advancements over prior art approaches.

1. In various embodiments, a computer-implemented method for displaying a prompt history comprises displaying a prompt space as a volumetric room, retrieving a prompt card that includes a record of one or more interactions with a machine learning (ML) model when generating a target design object, and displaying the prompt card within the prompt space.

2. The computer-implemented method of clause 1, where the record includes a prompt that has been provided to the ML model, and a design object generated by the ML model in response to the prompt.

3. The computer-implemented method of clause 1 or 2, further comprising detecting a selection of the design object, and displaying the design object within a design space.

4. The computer-implemented method of any of clauses 1-3, where the prompt space at least partially overlaps a design space that includes a three-dimensional design.

5. The computer-implemented method of any of clauses 1-4, where the one or more interactions are included in a communication session with the ML model.

6. The computer-implemented method of any of clauses 1-5, where the record comprises a multimodal prompt including at least two of a design intent text or one or more non-textual inputs, and wherein the one or more non-textual inputs includes at least one of: a computer-aided design (CAD) object, a geometry, an image, a sketch, a video, an application state, or an audio recording.

7. The computer-implemented method of any of clauses 1-6, further comprising, retrieving one or more additional prompt cards, wherein each of the one or more additional prompt cards including one or more additional records, each of the one or more additional records including one or more additional interactions with the ML model, displaying the one or more additional prompt cards within the prompt space, and arranging, based on one or more criteria, the prompt card and the one or more additional prompt cards within the prompt space, wherein the one or more criteria comprises at least one of author, date created, object type, or one or more keywords.

8. The computer-implemented method of any of clauses 1-7, where the one or more additional prompt cards include a first prompt card including a first record of a first interaction generated by a first user and the ML model, and a second prompt card including a second record of a second interaction generated by a second user and the ML model.

9. The computer-implemented method of any of clauses 1-8, further comprising determining a selection of a portion of the prompt card, and in response, generating a prompt including the portion of the prompt card.

10. The computer-implemented method of any of clauses 1-9, further comprising detecting at least one of a line along a path added within the prompt space, or a gestural interaction performed within the prompt space, determining two or more prompt cards within the prompt space that are proximate to the line or the gestural interaction, and linking the two or more prompt cards.

11. The computer-implemented method of any of clauses 1-10, further comprising detecting at least one of a line along a path added within the prompt space that at least partially overlaps the prompt card, or a gestural interaction performed within the prompt space that at least partially overlaps the prompt card, determining an intent associated with the line or the gestural interaction, and modifying the prompt space based on the intent.

12. In various embodiments, one or more non-transitory computer-readable media include instructions that, when executed by one or more processors, cause the one or more processors to display a prompt history by performing the steps of displaying a prompt space as a volumetric room, retrieving a prompt card that includes a record of one or more interactions with a machine learning (ML) model when generating a target design object, and displaying the prompt card within the prompt space.

13. The one or more non-transitory computer-readable media of clause 12, further including instructions that, when executed by the one or more processors, cause the one or more processors to perform the steps of determining a selection of a portion of the prompt card identifying one or more keywords associated with the portion of the prompt card, and displaying a contextual menu including one or more prompt cards associated with the one or more keywords.

14. The one or more non-transitory computer-readable media of clause 12 or 13, further including instructions that, when executed by the one or more processors, cause the one or more processors to perform the steps of determining a selection of a portion of the prompt card, identifying an image included in the portion of the prompt card, identifying one or more objects associated with the image, and displaying a contextual menu including one or more prompt cards associated with the one or more objects.

15. The one or more non-transitory computer-readable media of any of claims 12-14, further including instructions that, when executed by the one or more processors, cause the one or more processors to perform the steps of detecting a selection of a design object included in the record, wherein the record includes a prompt that has been provided to the ML model, and the design object was generated by the ML model in response to the prompt, and displaying the design object within a design space.

16. The one or more non-transitory computer-readable media of any of clauses 12-15, where the prompt space at least partially overlaps a design space that includes a three-dimensional design.

17. The one or more non-transitory computer-readable media of any of clauses 12-16, further including instructions that, when executed by the one or more processors, cause the one or more processors to perform the steps of retrieving one or more additional prompt cards, wherein each of the one or more additional prompt cards including one or more additional records, each of the one or more additional records including one or more additional interactions with the ML model, displaying the one or more additional prompt cards within the prompt space, and arranging, based on one or more criteria, the prompt card and the one or more additional prompt cards within the prompt space, wherein the one or more criteria comprises at least one of author, date created, object type, or one or more keywords.

18. The one or more non-transitory computer-readable media of any of clauses 12-17, where the one or more additional prompt cards include a first prompt card including a first record of a first interaction generated by a first user and the ML model, and a second prompt card including a second record of a second interaction generated by a second user and the ML model.

19. The one or more non-transitory computer-readable media of any of clauses 12-18, further including instructions that, when executed by the one or more processors, cause the one or more processors to perform the steps of determining a selection of a portion of the prompt card, and in response, generating a prompt including the portion of the prompt card.

20. In various embodiments, a system comprises one or more memories storing instructions, and one or more processors coupled to the one or more memories that, when executing the instructions, perform the steps of displaying a prompt space as a volumetric room, retrieving a prompt card that includes a record of one or more interactions with a machine learning (ML) model when generating a target design object, and displaying the prompt card within the prompt space.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for displaying a prompt history, the method comprising:
displaying a prompt space as a volumetric room;
retrieving a prompt card that includes a record of one or more interactions with a machine learning (ML) model when generating a target design object; and
displaying the prompt card within the prompt space.

2. The computer-implemented method of claim 1, wherein the record includes:
a prompt that has been provided to the ML model; and
a design object generated by the ML model in response to the prompt.

3. The computer-implemented method of claim 2, further comprising:
detecting a selection of the design object; and
displaying the design object within a design space.

4. The computer-implemented method of claim 1, wherein the prompt space at least partially overlaps a design space that includes a three-dimensional design.

5. The computer-implemented method of claim 1, wherein the one or more interactions are included in a communication session with the ML model.

6. The computer-implemented method of claim 1, wherein the record comprises a multimodal prompt including at least two of a design intent text or one or more non-textual inputs, and wherein the one or more non-textual inputs includes at least one of: a computer-aided design (CAD) object, a geometry, an image, a sketch, a video, an application state, or an audio recording.

7. The computer-implemented method of claim 1, further comprising:
retrieving one or more additional prompt cards, wherein each of the one or more additional prompt cards including one or more additional records, each of the one or more additional records including one or more additional interactions with the ML model;
displaying the one or more additional prompt cards within the prompt space; and
arranging, based on one or more criteria, the prompt card and the one or more additional prompt cards within the prompt space, wherein the one or more criteria comprises at least one of author, date created, object type, or one or more keywords.

8. The computer-implemented method of claim 7, wherein the one or more additional prompt cards include:
a first prompt card including a first record of a first interaction generated by a first user and the ML model; and
a second prompt card including a second record of a second interaction generated by a second user and the ML model.

9. The computer-implemented method of claim 1, further comprising:
determining a selection of a portion of the prompt card; and
in response, generating a prompt including the portion of the prompt card.

10. The computer-implemented method of claim 1, further comprising:
detecting at least one of:
a line along a path added within the prompt space, or
a gestural interaction performed within the prompt space;
determining two or more prompt cards within the prompt space that are proximate to the line or the gestural interaction; and
linking the two or more prompt cards.

11. The computer-implemented method of claim 1, further comprising:
detecting at least one of:
a line along a path added within the prompt space that at least partially overlaps the prompt card, or
a gestural interaction performed within the prompt space that at least partially overlaps the prompt card;
determining an intent associated with the line or the gestural interaction; and
modifying the prompt space based on the intent.

12. One or more non-transitory computer-readable media including instructions that, when executed by one or more processors, cause the one or more processors to display a prompt history by performing the steps of:
displaying a prompt space as a volumetric room;
retrieving a prompt card that includes a record of one or more interactions with a machine learning (ML) model when generating a target design object; and
displaying the prompt card within the prompt space.

13. The one or more non-transitory computer-readable media of claim 12, further including instructions that, when executed by the one or more processors, cause the one or more processors to perform the steps of:
determining a selection of a portion of the prompt card;
identifying one or more keywords associated with the portion of the prompt card; and
displaying a contextual menu including one or more prompt cards associated with the one or more keywords.

14. The one or more non-transitory computer-readable media of claim 12, further including instructions that, when executed by the one or more processors, cause the one or more processors to perform the steps of:
determining a selection of a portion of the prompt card;
identifying an image included in the portion of the prompt card;
identifying one or more objects associated with the image; and
displaying a contextual menu including one or more prompt cards associated with the one or more objects.

15. The one or more non-transitory computer-readable media of claim 12, further including instructions that, when executed by the one or more processors, cause the one or more processors to perform the steps of:
detecting a selection of a design object included in the record, wherein the record includes a prompt that has been provided to the ML model, and the design object was generated by the ML model in response to the prompt; and
displaying the design object within a design space.

16. The one or more non-transitory computer-readable media of claim 12, wherein the prompt space at least partially overlaps a design space that includes a three-dimensional design.

17. The one or more non-transitory computer-readable media of claim 12, further including instructions that, when executed by the one or more processors, cause the one or more processors to perform the steps of:
retrieving one or more additional prompt cards, wherein each of the one or more additional prompt cards including one or more additional records, each of the one or more additional records including one or more additional interactions with the ML model;
displaying the one or more additional prompt cards within the prompt space; and
arranging, based on one or more criteria, the prompt card and the one or more additional prompt cards within the prompt space, wherein the one or more criteria comprises at least one of author, date created, object type, or one or more keywords.

18. The one or more non-transitory computer-readable media of claim 17, wherein the one or more additional prompt cards include:
a first prompt card including a first record of a first interaction generated by a first user and the ML model; and
a second prompt card including a second record of a second interaction generated by a second user and the ML model.

19. The one or more non-transitory computer-readable media of claim 12, further including instructions that, when executed by the one or more processors, cause the one or more processors to perform the steps of:
determining a selection of a portion of the prompt card; and
in response, generating a prompt including the portion of the prompt card.

20. A system comprising:
one or more memories storing instructions; and
one or more processors coupled to the one or more memories that, when executing the instructions, perform the steps of:
displaying a prompt space as a volumetric room;
retrieving a prompt card that includes a record of one or more interactions with a machine learning (ML) model when generating a target design object; and
displaying the prompt card within the prompt space.
